(19) United States
(12) Patent Application Publication
(10) Pub. No.: US 2024/0147710 A1
(43) Pub. Date: May 2, 2024

(54) SEMICONDUCTOR DEVICE

(71) Applicant: Samsung Electronics Co., Ltd., Suwon-si (KR)

(72) Inventors: Jongmin KIM, Suwon-si (KR); Chansic YOON, Suwon-si (KR)

(73) Assignee: Samsung Electronics Co., Ltd., Suwon-si (KR)

(21) Appl. No.: 18/457,756

(22) Filed: Aug. 29, 2023

(30) Foreign Application Priority Data
Oct. 27, 2022 (KR) 10-2022-0140506

(51) Int. Cl. H10B 12/00

(52) U.S. Cl. CPC H10B 12/50; H10B 12/09; H10B 12/315

(57) ABSTRACT

A semiconductor device may include a substrate including a cell region and a connection region, a cell word line extending across the plurality of active regions in a first horizontal direction on the cell region of the substrate, a cell bit line including a cell metallic conductive pattern extending on the cell region of the substrate in a second horizontal direction, and a connection bit line including a connection metallic conductive pattern extending in the second horizontal direction on the connection region of the substrate. A top surface of the connection bit line may be located at a vertical level that is equal to or lower than a top surface of the cell bit line, and a height of the connection metallic conductive pattern in a vertical direction may be equal to or greater than a height of the cell metallic conductive pattern in the vertical direction.

### CROSS-REFERENCE TO RELATED APPLICATION

This application is based on and claims priority under 35 U.S.C. § 119 to Korean Patent Application No. 10-2022-0140506, filed on Oct. 27, 2022 in the Korean Intellectual Property Office, the disclosure of which is incorporated by reference herein in its entirety.

### BACKGROUND

Inventive concepts relate to a semiconductor device.

Electronic devices have become more compact and lightweight according to the rapid development of the electronics industry and the demands of users. Accordingly, semiconductor devices having high integration, which are used in electronic devices, may be required, and thus, design rules for components of semiconductor devices have been reduced.

### SUMMARY

Inventive concepts provide a semiconductor device having improved electrical connection.

Aspect of embodiments of inventive concepts are not limited to the above-mentioned aspects, and other aspects not mentioned may be clearly understood by one of ordinary skill in the art from the following description.

According to an embodiment of inventive concepts, a semiconductor device may include a substrate including a cell region and a connection region around the cell region; a plurality of cell device isolation layers in the cell region of the substrate, the plurality of device isolation layers defining a plurality of active regions in the cell region of the substrate; a cell word line extending across the plurality of active regions in a first horizontal direction on the cell region of the substrate; a cell bit line including a cell metallic conductive pattern, the cell metallic conductive pattern extending on the cell region of the substrate in a second horizontal direction, the second horizontal direction intersecting the first horizontal direction; and a connection bit line including a connection metallic conductive pattern, the connection metallic conductive pattern extending in the second horizontal direction on the connection region of the substrate. A top surface of the connection bit line may be located at a vertical level that is equal to or lower than a top surface of the cell bit line. A height of the connection metallic conductive pattern in a vertical direction may be equal to or greater than a height of the cell metallic conductive pattern in the vertical direction.

According to an embodiment of inventive concepts, a semiconductor device may include a substrate including a cell region and a connection region around the cell region; a plurality of cell device isolation layers in the cell region of the substrate, the plurality of cell device isolation layers defining a plurality of active regions in the cell region of the substrate; a cell word line extending across the plurality of active regions in a first horizontal direction on the cell region of the substrate; a cell bit line including a cell conductive semiconductor pattern, the cell conductive semiconductor pattern extending on the cell region of the substrate in a second horizontal direction, the second horizontal direction intersecting the first horizontal direction; and a connection bit line including a connection conductive semiconductor pattern, the connection conductive semiconductor pattern extending in the second horizontal direction on the connection region of the substrate. The connection conductive semiconductor pattern may include a portion having a lower height in a vertical direction than a height of the cell conductive semiconductor pattern in the vertical direction.

According to an embodiment of inventive concepts, a semiconductor device may include a substrate including a cell region and a connection region around the cell region; a cell device isolation layer in the cell region of the substrate, the cell device isolation layer defining an active region in the cell region of the substrate; a cell word line extending across the active region in a first horizontal direction on the cell region of the substrate; a cell bit line extending on the cell region of the substrate in a second horizontal direction, the second horizontal direction intersecting the first horizontal direction; and a connection bit line extending in the second horizontal direction on the connection region of the substrate. The cell bit line may include a cell conductive semiconductor pattern and a cell metallic conductive pattern on the cell conductive semiconductor pattern. The connection bit line may include a connection conductive semiconductor pattern and a connection metallic conductive pattern on the connection conductive semiconductor pattern. The cell conductive semiconductor pattern and the connection conductive semiconductor pattern each may include polysilicon. A top surface of the connection conductive semiconductor pattern may be located at a vertical level that is equal to or lower than a top surface of the cell conductive semiconductor pattern. A vertical level difference between a top surface of the connection metallic conductive pattern and a top surface of the cell metallic conductive pattern may be equal to or less than a vertical level difference between a bottom surface of the connection metallic conductive pattern and a bottom surface of the cell metallic conductive pattern.

### BRIEF DESCRIPTION OF THE DRAWINGS

Embodiments will be more clearly understood from the following detailed description taken in conjunction with the accompanying drawings in which:

FIG. 1 is a schematic layout diagram of a semiconductor device according to an embodiment;

FIG. 2 is a schematic layout diagram of a region R1 of FIG. 1;

FIGS. 3A to 3D are cross-sectional views taken along lines A-A′, B-B′, C-C′, and D-D′ of FIG. 2;

FIG. 4 is a schematic layout diagram of a region R2 of FIG. 1;

FIGS. 5A, 6A, and 7A are cross-sectional views of a semiconductor device corresponding to a cross section taken along line E-E′ of FIG. 4, according to an embodiment;

FIGS. 5B, 6B, and 7B are cross-sectional views taken along lines I-I and II-II of FIGS. 5A, 6A, and 7A, respectively;

FIGS. 8A and 8B are cross-sectional views of a semiconductor device corresponding to a cross section taken along line E-E′ of FIG. 4, according to an embodiment; and

FIGS. 9 to 16C are cross-sectional views illustrating a method of manufacturing a semiconductor device, according to an embodiment.

### DETAILED DESCRIPTION

Hereinafter, embodiments will be described in detail with reference to the accompanying drawings.

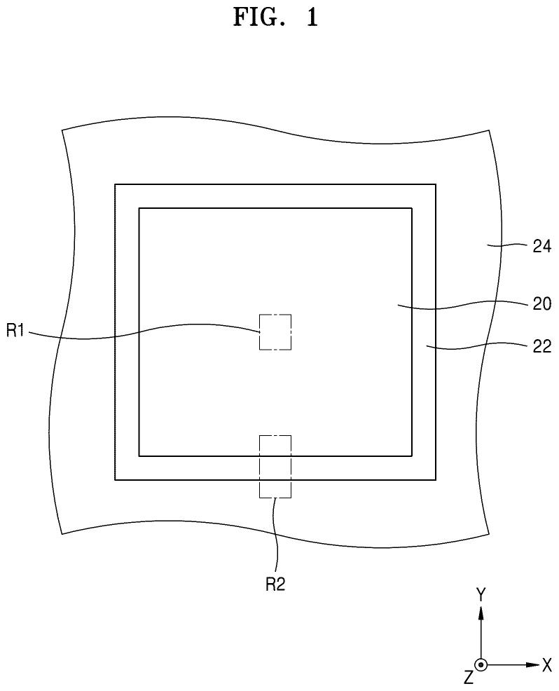

FIG. 1 is a schematic layout diagram of a semiconductor device according to an embodiment.

Referring to FIG. 1, a semiconductor device according to an embodiment may include a cell region 20, a connection region 22, and a peripheral circuit region 24. The connection region 22 may be formed along a circumference of the cell region 20. The connection region 22 may be formed between the cell region 20 and the peripheral circuit region 24, and may isolate the cell region 20 from the peripheral circuit region 24. The peripheral circuit region 24 may be defined around the cell region 20.

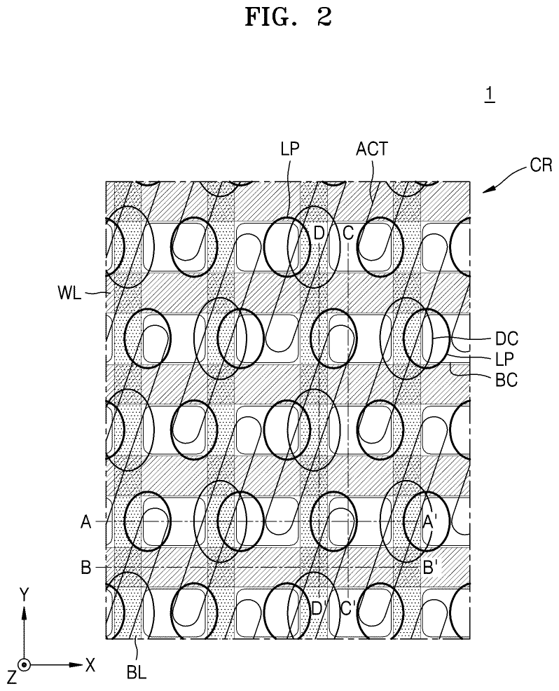

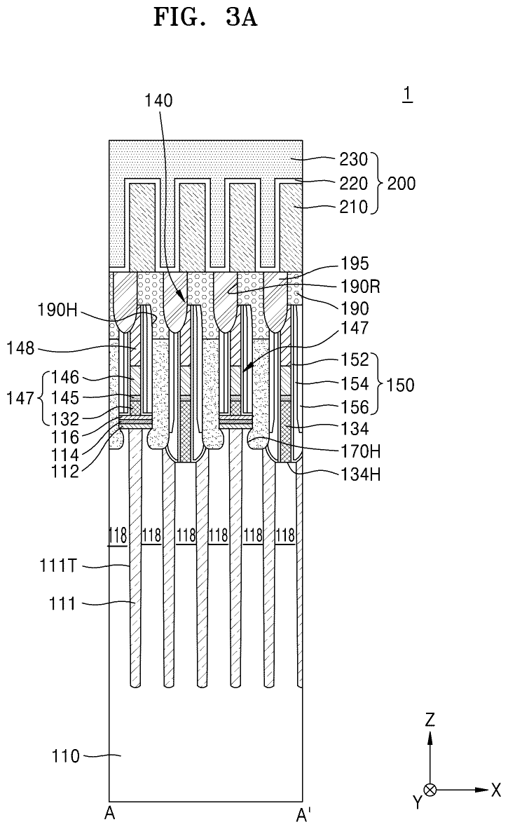

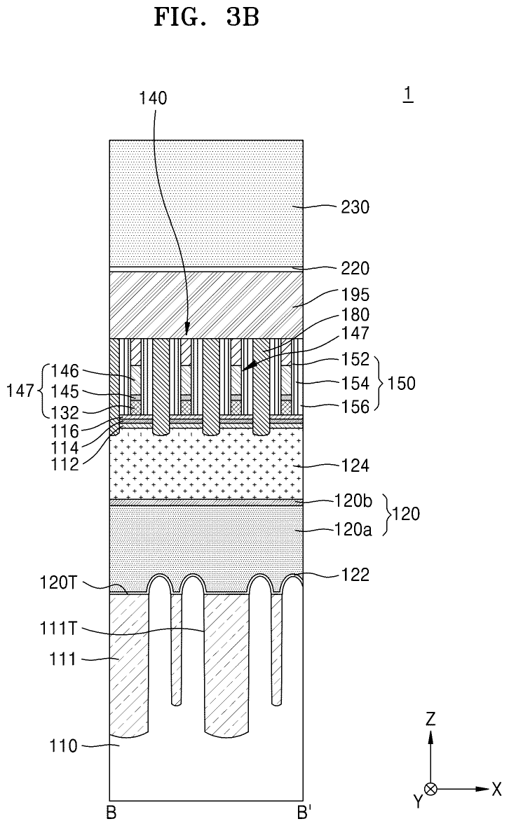

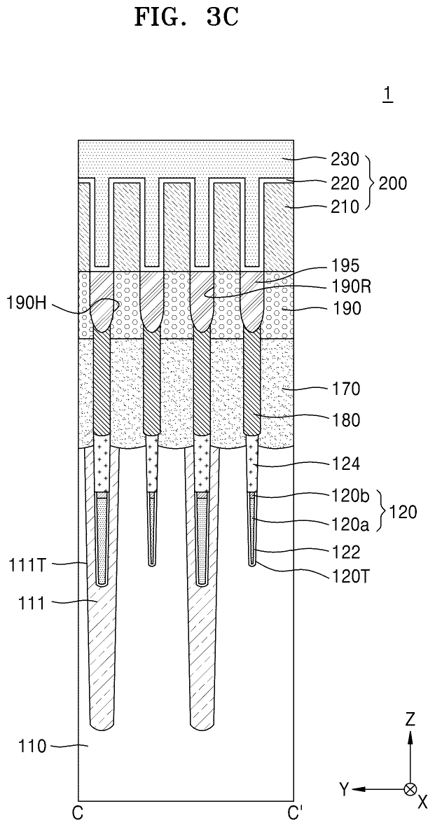

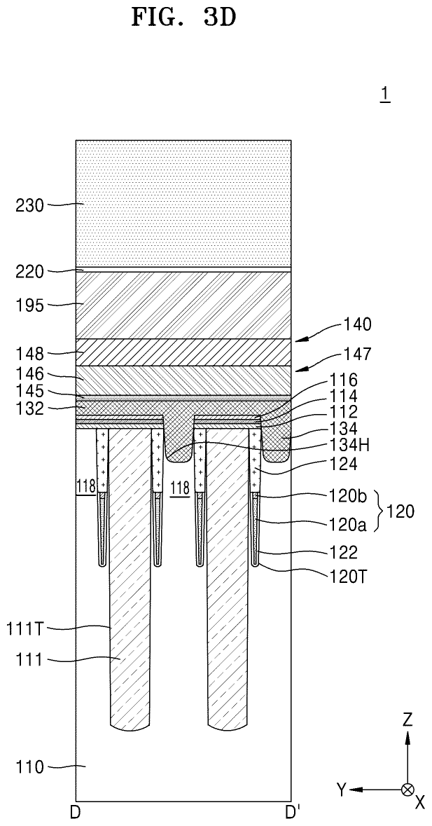

FIG. 2 is a schematic layout diagram of a region R1 of FIG. 1, and illustrates main components of a semiconductor device according to an embodiment. FIGS. 3A to 3D are cross-sectional views taken along lines A-A′, B-B′, C-C′, and D-D′ of FIG. 2.

Referring to FIG. 2, a semiconductor device 1 may include a plurality of active regions ACT formed in a memory cell region CR. The memory cell region CR may correspond to the cell region 20 of FIG. 1. In some embodiments, the plurality of active regions ACT arranged in the memory cell region CR may be arranged to have a major axis in a diagonal direction with respect to a first horizontal direction (an X direction) and a second horizontal direction (a Y direction). The plurality of active regions ACT may constitute a plurality of active regions 118 illustrated in FIGS. 3A and 3D.

A plurality of word lines WL may extend parallel to each other in the first horizontal direction (the X direction) across the plurality of active regions ACT. On the plurality of word lines WL, a plurality of bit lines BL may extend parallel to each other in the second horizontal direction (the Y direction) intersecting the first horizontal direction (the X direction).

In some embodiments, a plurality of buried contacts BC may be formed between two adjacent bit lines BL from among the plurality of bit lines BL. In some embodiments, the plurality of buried contacts BC may be arranged in a line in each of the first horizontal direction (the X direction) and the second horizontal direction (the Y direction).

A plurality of landing pads LP may be formed on the plurality of buried contacts BC. The plurality of landing pads LP may be arranged to at least partially overlap the plurality of buried contacts BC. In some embodiments, each of the plurality of landing pads LP may extend to a top portion of any one bit line BL from among two adjacent bit lines BL.

A plurality of storage nodes (not shown) may be formed on the plurality of landing pads LP. The plurality of storage nodes may be formed on the plurality of bit lines BL. The plurality of storage nodes may be respectively lower electrodes of a plurality of capacitors. The storage node may be connected to the active region ACT through the landing pad LP and the buried contact BC.

The semiconductor device 1 may be a dynamic random access memory (DRAM) device.

Referring to FIGS. 3A to 3D together, the semiconductor device 1 includes a plurality of active regions 118 defined by a device isolation layer 111, and includes a substrate 110 having a plurality of word line trenches 120T crossing the plurality of active regions 118, a plurality of word lines 120 arranged inside the plurality of word line trenches 120T, a plurality of bit line structures 140, and a plurality of capacitor structures 200 including a plurality of lower electrodes 210, a capacitor dielectric layer 220, and an upper electrode 230.

The substrate 110 may include, for example, silicon (Si), crystalline Si, polycrystalline Si, or amorphous Si. In some embodiments, the substrate 110 may include a semiconductor element such as germanium (Ge), or at least one compound semiconductor selected from silicon germanium (SiGe), silicon carbide (SiC), gallium arsenide (GaAs), indium arsenide (InAs), and indium phosphide (InP). In some embodiments, the substrate 110 may have a silicon on insulator (SOI) structure. For example, the substrate 110 may include a buried oxide (BOX) layer. The substrate 110 may include a conductive region, for example, a well doped with impurities, or a structure doped with impurities.

The plurality of active regions 118 may be portions of the substrate 110 defined by a device isolation trench 111T. The plurality of active regions 118 may have a relatively long island shape having a short axis and a long axis in a plan view. In some embodiments, the plurality of active regions 118 may be arranged to have a major axis in the diagonal direction with respect to the first horizontal direction (the X direction) and the second horizontal direction (the Y direction). The plurality of active regions 118 may extend to have substantially the same length in a long axis direction, and may be repeatedly arranged to have mostly a constant pitch.

The device isolation layer 111 may fill the device isolation trench 111T. The plurality of active regions 118 may be defined in the substrate 110 by the device isolation layer 111.

In some embodiments, the device isolation layer 111 may include a triple layer including a first device isolation layer, a second device isolation layer, and a third device isolation layer, but is not limited thereto. For example, the first device isolation layer may conformally cover an inner side surface and a bottom surface of the device isolation trench 111T. In some embodiments, the first device isolation layer may include silicon oxide. For example, the second device isolation layer may conformally cover the first device isolation layer. In some embodiments, the second device isolation layer may include silicon nitride. For example, the third device isolation layer may cover the second device isolation layer and fill the device isolation trench 111T. In some embodiments, the third device isolation layer may include silicon oxide. For example, the third device isolation layer may include silicon oxide including tonen silazene (TOSZ). In some embodiments, the device isolation layer 111 may include a single layer formed of one type of insulating layer, a double layer formed of two types of insulating layers, or a multilayer formed of a combination of at least four types of insulating layers. For example, the device isolation layer 111 may include a single layer including silicon oxide.

The plurality of word line trenches 120T may be formed in the substrate 110 including the plurality of active regions 118 defined by the device isolation layer 111. The plurality of word line trenches 120T may extend parallel to each other in the first horizontal direction (the X direction), and may each have a line shape that is arranged to cross the active region 118 and have approximately equal intervals in the second horizontal direction (the Y direction). In some embodiments, stepped portion may be formed on bottom surfaces of the plurality of word line trenches 120T.

A plurality of gate dielectric layers 122, a plurality of word lines 120, and a plurality of dummy buried insulating layers 124 may be sequentially formed inside the plurality of word line trenches 120T. The plurality of word lines 120 may constitute the plurality of word lines WL illustrated in FIG. 2. The plurality of word lines 120 may extend in parallel in the first horizontal direction (the X direction), and may each have a line shape that is arranged to cross the active region 118 and have approximately equal intervals in the second horizontal direction (the Y direction). A top surface of each of the plurality of word lines 120 may be located at a lower vertical level than a top surface of the substrate 110. Bottom surfaces of the plurality of word lines 120 may have an uneven shape, and saddle fin field effect transistors (FinFETs) having a saddle fin structure may be formed in the plurality of active regions 118.

The plurality of word lines 120 may fill lower portions of the plurality of word line trenches 120T. Each of the plurality of word lines 120 may have a stacked structure of a lower word line layer 120a and an upper word line layer 120b. For example, the lower word line layer 120a may conformally cover an inner wall and a bottom surface of a lower portion of the word line trench 120T with the gate dielectric layer 122 therebetween. For example, the upper word line layer 120b may cover the lower word line layer 120a, and may fill a lower portion of the word line trench 120 with the gate dielectric layer 122 therebetween. In some embodiments, the lower word line layer 120a may include a metal material, such as Ti, TiN, Ta, or TaN, or conductive metal nitride. In some embodiments, the upper word line layer 120b may include, for example, doped polysilicon, a metal material such as W, conductive metal nitride such as WN, TiSiN, or WSiN, or a combination thereof.

A source region and a drain region formed by implanting impurity ions into a portion of the active region 118 may be arranged in the portion of the active region 118 of the substrate 110 on both sides of each of the plurality of word lines 120.

The gate dielectric layer 122 may cover an inner wall and a bottom surface of the word line trench 120T. In some embodiments, the gate dielectric layer 122 may extend from between the word line 120 and the word line trench 120T to between the dummy buried insulating layer 124 and the word line trench 120T. The gate dielectric layer 122 may include at least one selected from silicon oxide, silicon nitride, silicon oxynitride, oxide/nitride/oxide (ONO), and a high-k dielectric material having a higher dielectric constant than silicon oxide. For example, the gate dielectric layer 122 may have a dielectric constant of about 10 to about 25. In some embodiments, the gate dielectric layer 122 may include at least one material selected from hafnium oxide (HfO), hafnium silicate (HfSiO), hafnium oxynitride (HfON), hafnium silicon oxynitride (HfSiON), lanthanum oxide (LaO), lanthanum aluminum oxide (LaAlO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), strontium titanium oxide (SrTiO), yttrium oxide (YO), aluminum oxide (AlO), and lead scandium tantalum oxide (PbScTaO). For example, the gate dielectric layer 122 may include HfO₂, Al₂O₃, HfAlO₃, Ta₂O₃, or TiO₂.

The plurality of dummy buried insulating layers 124 may fill upper portions of the plurality of word line trenches 120T. In some embodiments, top surfaces of the plurality of dummy buried insulating layers 124 may be located at substantially the same vertical level as a top surface of the substrate 110. The dummy buried insulating layer 124 may include at least one material layer selected from silicon oxide, silicon nitride, silicon oxynitride, and a combination thereof. For example, the dummy buried insulating layer 124 may include silicon nitride.

Insulating layers 112, 114, and 116 may be disposed on the device isolation layer 111, the plurality of active regions 118, and the plurality of dummy buried insulating layers 124. For example, the insulating layers 112, 114, and 116 may include silicon oxide, silicon nitride, silicon oxynitride, a metallic dielectric, or a combination thereof. In some embodiments, the insulating layers 112, 114, and 116 may have a stacked structure of a plurality of insulating layers including a first insulating layer 112, a second insulating layer 114, and a third insulating layer 116. In some embodiments, the first insulating layer 112 may include silicon oxide, the second insulating layer 114 may include silicon oxynitride, and the third insulating layer 116 may include silicon oxide. In some embodiments, the first insulating layer 112 may include a non-metallic dielectric, the second insulating layer 114 may include a metallic dielectric, and the third insulating layer 116 may include a non-metallic dielectric. In some embodiments, the second insulating layer 114 may be thicker than the first insulating layer 112. For example, the first insulating layer 112 may have a thickness of about 50 Å to about 90 Å, and the second insulating layer 114 may have a thickness of about 60 Å to about 100 Å, which is greater than the thickness of the first insulating layer 112.

A plurality of direct contact conductive patterns 134 may fill portions of a plurality of direct contact holes 134H that passes through the insulating layers 112, 114, and 116 to expose the source region in the active region 118. In some embodiments, the direct contact hole 134H may extend into the active region 118, i.e., into the source region. The direct contact conductive pattern 134 may include, for example, doped polysilicon. In some embodiments, the direct contact conductive pattern 134 may include an epitaxial silicon layer. The plurality of direct contact conductive patterns 134 may constitute a plurality of direct contacts DC illustrated in FIG. 2.

A plurality of bit line structures 140 may be disposed on the insulating layers 112, 114, and 116. Each of the plurality of bit line structures 140 may include a bit line 147 and an insulating capping line 148 covering the bit line 147. The plurality of bit line structures 140 may extend parallel to each other in the second horizontal direction (the Y direction) parallel to a main surface of the substrate 110. A plurality of bit lines 147 may constitute the plurality of bit lines BL illustrated in FIG. 2. The plurality of bit lines 147 may be electrically connected to the plurality of active regions 118 through the plurality of direct contact conductive patterns 134. In some embodiments, a plurality of insulating capping lines 148 may include silicon nitride.

The bit line 147 may have a stacked structure of a first cell metallic conductive pattern 145 and a second cell metallic conductive pattern 146 having a line shape. In some embodiments, the first cell metallic conductive pattern 145 may include titanium nitride (TiN) or Ti—Si—N (TSN), and the second metallic conductive pattern 146 may include tungsten (W), or tungsten (W) and tungsten silicide (WSiₓ). In some embodiments, the first cell metallic conductive pattern 145 may operate as a diffusion barrier.

In some embodiments, the plurality of bit lines 147 may further include a conductive semiconductor pattern 132 arranged between the insulating layers 112, 114, and 116 and the first and second cell metallic conductive patterns 145 and 146. The conductive semiconductor pattern 132 may include, for example, doped polysilicon.

A plurality of insulating spacer structures 150 may cover both sidewalls of the plurality of bit line structures 140. Each of the plurality of insulating spacer structures 150 may include a first insulating spacer 152, a second insulating spacer 154, and a third insulating spacer 156. In some embodiments, the plurality of insulating spacer structures 150 may extend into the plurality of direct contact holes 134H to cover both sidewalls of the plurality of direct contact conductive patterns 134. The second insulating spacer 154 may include a material having a lower dielectric constant than the first insulating spacer 152 and the third insulating spacer 156. In some embodiments, the first insulating spacer 152 and the third insulating spacer 156 may include nitride, and the second insulating spacer 154 may include oxide. In some embodiments, the first insulating spacer 152 and the third insulating spacer 156 may include nitride, and the second insulating spacer 154 may include a material having etch selectivity with respect to the first insulating spacer 152 and the third insulating spacer 156. For example, the first insulating spacer 152 and the second insulating spacer 156 may include nitride, and the second insulating spacer 154 may be an air spacer. In some embodiments, the insulating spacer structure 150 may include the second insulating spacer 154 including oxide and the third insulating spacer 156 including nitride.

Each of a plurality of insulating fences 180 may be located in a space between a pair of insulating spacer structures 150 facing each other between a pair of adjacent bit line structures 140. The plurality of insulating fences 180 may be spaced apart from each other and may be arranged in a row, between the pair of insulating spacer structures 150 facing each other, i.e., in the second horizontal direction (the Y direction). For example, the plurality of insulating fences 180 may include nitride.

In some embodiments, the plurality of insulating fences 180 may be formed to pass through the insulating layers 112, 114, and 116 and extend into the dummy buried insulating layer 124, but are not limited thereto. In some embodiments, the plurality of insulating fences 180 may be formed to pass through the insulating layers 112, 114, and 116 but not to extend into the dummy buried insulating layer 124, may be formed to extend into the insulating layers 112, 114, and 116 but not to pass through the insulating layers 112, 114, and 116, or may be formed not to extend into the insulating layers 112, 114, and 116 so that bottom surfaces thereof contact the insulating layers 112, 114, and 116.

Between the plurality of bit lines 147, a plurality of buried contact holes 170H may be defined between the plurality of insulating fences 180. The plurality of buried contact holes 170H and the plurality of insulating fences 180 may be alternately arranged between a pair of insulating spacer structures 150 facing each other from among the plurality of insulating spacer structures 150 covering both sidewalls of the plurality of bit line structures 140, i.e., in the second horizontal direction (the Y direction). The plurality of buried contact holes 170H may have internal spaces defined by the insulating spacer structure 150 covering, between two adjacent bit lines 147 from among the plurality of bit lines 147, sidewalls of each of the two adjacent bit lines 147, the insulating fence 180, and the active region 118. In some embodiments, each of the plurality of buried contact holes 170H may extend from between the insulating spacer structure 150 and the insulating fence 180 into the active region 118.

A plurality of buried contacts 170 may be arranged in the plurality of buried contact holes 170H. The plurality of buried contacts 170 may fill a lower portion of a space between the plurality of insulating fences 180 and the plurality of insulating spacer structures 150 covering both sidewalls of each of the plurality of bit line structures 140. The plurality of buried contacts 170 and the plurality of insulating fences 180 may be alternately arranged between a pair of insulating spacer structures 150 facing each other from among the plurality of insulating spacer structures 150 covering both sidewalls of the plurality of bit line structures 140, i.e., in the second horizontal direction (the Y direction). For example, the plurality of buried contacts 170 may include polysilicon.

In some embodiments, the plurality of buried contacts 170 may be arranged in a line in each of the first horizontal direction (the X direction) and the second horizontal direction (the Y direction). Each of the plurality of buried contacts 170 may extend from the active region 118 in a vertical direction (a Z direction) perpendicular to the substrate 110. The plurality of buried contacts 170 may constitute the plurality of buried contacts BC illustrated in FIG. 2.

A level of top surfaces of the plurality of buried contacts 170 may be located lower than a level of top surfaces of the plurality of insulating capping lines 148. Top surfaces of the plurality of insulating fences 180 and the top surfaces of the plurality of insulating capping lines 148 may be located at the same vertical level with respect to the vertical direction (the Z direction).

A plurality of landing pad holes 190H may be defined by the plurality of buried contacts 170, the plurality of insulating spacer structures 150, and the plurality of insulating fences 180. The plurality of buried contacts 170 may be exposed at bottoms of the plurality of landing pad holes 190H.

A plurality of landing pads 190 may fill at least portions of the plurality of landing pad holes 190H, and may extend onto the plurality of bit line structures 140. The plurality of landing pads 190 may be isolated from each other by a recess portion 190R. Each of the plurality of landing pads 190 may include a conductive barrier layer and a conductive pad material layer on the conductive barrier layer. For example, the conductive barrier layer may include metal, conductive metal nitride, or a combination thereof. In some embodiments, the conductive barrier layer may have a stacked structure of Ti/TiN. In some embodiments, the conductive pad material layer may include tungsten (W). In some embodiments, a metal silicide layer may be formed between the landing pad 190 and the buried contact 170. The metal silicide layer may include cobalt silicide (CoSix), nickel silicide (NiSix), or manganese silicide (MnSix), but is not limited thereto.

The plurality of landing pads 190 may be disposed on the plurality of buried contacts 170, and thus, the plurality of buried contacts 170 and the plurality of landing pads 190 corresponding to each other may be electrically connected to each other. The plurality of landing pads 190 may be connected to the active region 118 through the plurality of buried contacts 170. The plurality of landing pads 190 may constitute a plurality of landing pads LP illustrated in FIG. 2. The buried contact 170 may be arranged between two adjacent bit line structures 140, and the landing pad 190 may extend onto one bit line structure 140 from between two bit line structures 140 that are adjacent to each other with the buried contact 170 therebetween.

The recess portion 190R may be filled with an insulating structure 195. In some embodiments, the insulating structure 195 may include an interlayer insulating layer and an etch stop layer. For example, the interlayer insulating layer may include oxide, and the etch stop layer may include nitride. For example, the etch stop layer may include a silicon nitride layer or silicon boron nitride (SiBN). As illustrated in FIGS. 3A and 3C, a top surface of the insulating structure 195 and top surfaces of the plurality of landing pads 190 are located at the same vertical level, but are not limited thereto. For example, the insulating structure 195 may fill the recess portion 190R and cover the top surfaces of the plurality of landing pads 190, and thus may have the top surface located at a higher vertical level than the top surfaces of the plurality of landing pads 190.

A plurality of capacitor structures 200 including a plurality of lower electrodes 210, a capacitor dielectric layer 220, and an upper electrode 230 may be disposed on the plurality of landing pads 190 and the insulating structure 195. The lower electrode 210 and the landing pad 190 corresponding to each other may be electrically connected to each other. As illustrated in FIGS. 3A and 3C, the top surface of the insulating structure 195 and a bottom surface of the lower electrode 210 are located at the same vertical level, but are not limited thereto.

In some embodiments, the semiconductor device 1 may further include at least one support pattern that contacts sidewalls of a plurality of lower electrodes 210 to support the plurality of lower electrodes 210. The at least one support pattern may include any one material from among of silicon nitride (SiN), silicon carbonitride (SiCN), N-rich silicon nitride (N-rich SiN), and a Si-rich silicon nitride (Si-rich SiN), but is not limited thereto. In some embodiments, the at least one support pattern may include a plurality of support patterns that contact sidewalls of the plurality of lower electrodes 210 and are located at different vertical levels to be spaced apart from each other in the vertical direction (the Z direction).

Each of the plurality of lower electrodes 210 may have a column shape filled inside to have a circular horizontal cross section, i.e., a pillar shape, but is not limited thereto. In some embodiments, each of the plurality of lower electrodes 210 may have a cylinder shape with a lower portion closed. In some embodiments, the plurality of lower electrodes 210 may be arranged in a honeycomb shape arranged in a zigzag pattern with respect to the first horizontal direction (the X direction) or the second horizontal direction (the Y direction). In some embodiments, the plurality of lower electrodes 210 may be arranged in a matrix form arranged in a line in each of the first horizontal direction (the X direction) and the second horizontal direction (the Y direction). The plurality of lower electrodes 210 may include silicon doped with impurities, metal such as tungsten or copper, or a conductive metal compound such as titanium nitride. In some embodiments, the plurality of lower electrodes 210 may include TiN, CrN, VN, MoN, NbN, TiSiN, TiAlN, or TaAlN.

The capacitor dielectric layer 220 may conformally cover surfaces of the plurality of lower electrodes 210. In some embodiments, the capacitor dielectric layer 220 may be integrally formed to cover the surfaces of the plurality of lower electrodes 210 together within a certain region, for example, one memory cell region CR of FIG. 2.

The capacitor dielectric layer 220 may include a material having an antiferroelectricity characteristic, a material having a ferroelectricity characteristic, or a material having both an antiferroelectricity characteristic and a ferroelectricity characteristic. For example, the capacitor dielectric layer 220 may include silicon oxide, metal oxide, or a combination thereof. In some embodiments, the capacitor dielectric layer 220 may include a dielectric material including ABO₃ or MOₓ. For example, the capacitor dielectric layer 220 may include SiO, TaO, TaAlO, TaON, AlO, AlSiO, HfO, HfSiO, ZrO, RuO, WO, HfZrO, ZrSiO, TiO, TiAlO, VO, NbO, MoO, MnO, LaO YO, CoO, NiO, CuO, ZnO, FeO, SrO, BaO, (Ba,Sr)TiO (BST), SrTiO (STO), BaTiO (BTO), PbTiO (PTO), AgNbO, BiFeO, Pb(Zr,Ti)O (PZT), (Pb,La)(Zr,Ti)O, Ba(Zr,Ti)O, Sr(Zr,Ti)O, or a combination thereof.

The upper electrode 230 may be integrally formed on the plurality of lower electrodes 210 within a certain region, for example, one memory cell region CR of FIG. 2. The plurality of lower electrodes 210, the capacitor dielectric layer 220, and the upper electrode 230 may constitute the plurality of capacitor structures 200 within a certain region, for example, one memory cell region CR of FIG. 2.

The upper electrode 230 may include silicon doped with impurities, metal such as tungsten or copper, or a conductive metal compound such as titanium nitride. In some embodiments, the upper electrode 230 may include TiN, CrN, VN, MoN, NbN, TiSiN, TiAlN, or TaAlN. In some embodiments, the upper electrode 230 may have a stacked structure of at least two of a semiconductor material layer doped with impurities, a main electrode layer, and an interface layer. The doped semiconductor material layer may include, for example, doped polysilicon or doped polycrystalline silicon germanium poly (SiGe). The main electrode layer may include a metal material. The main electrode layer may include, for example, W, Ru, RuO, Pt, PtO, Ir, IrO, SrRuO (SRO), (Ba,Sr)RuO (BSRO), CaRuO (CRO), BaRuO, La(Sr,Co)O, or the like. In some embodiments, the main electrode layer may include W. The interface layer may include at least one of metal oxide, metal nitride, metal carbide, and metal silicide.

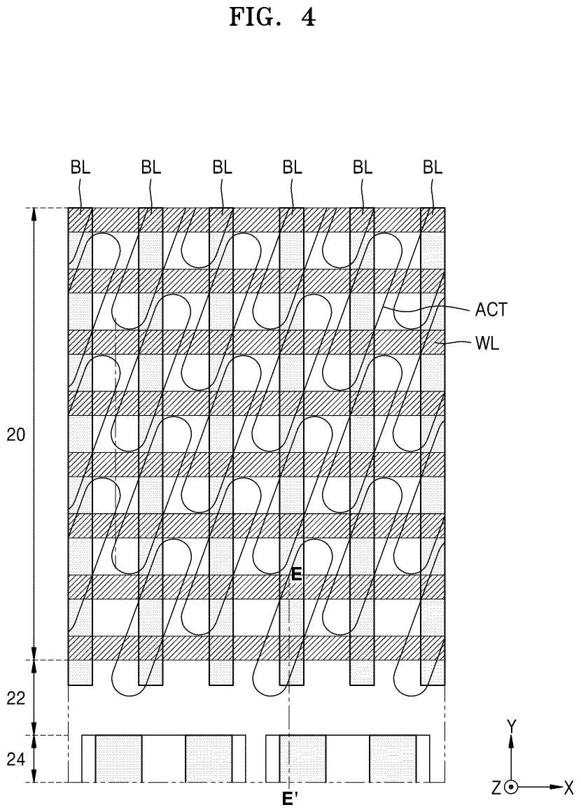

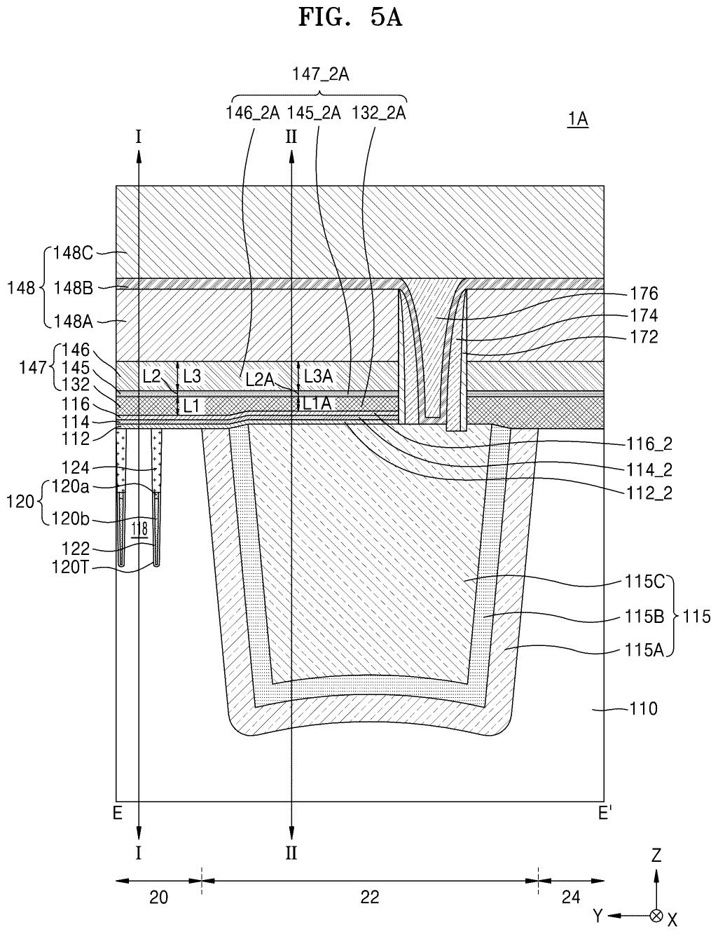

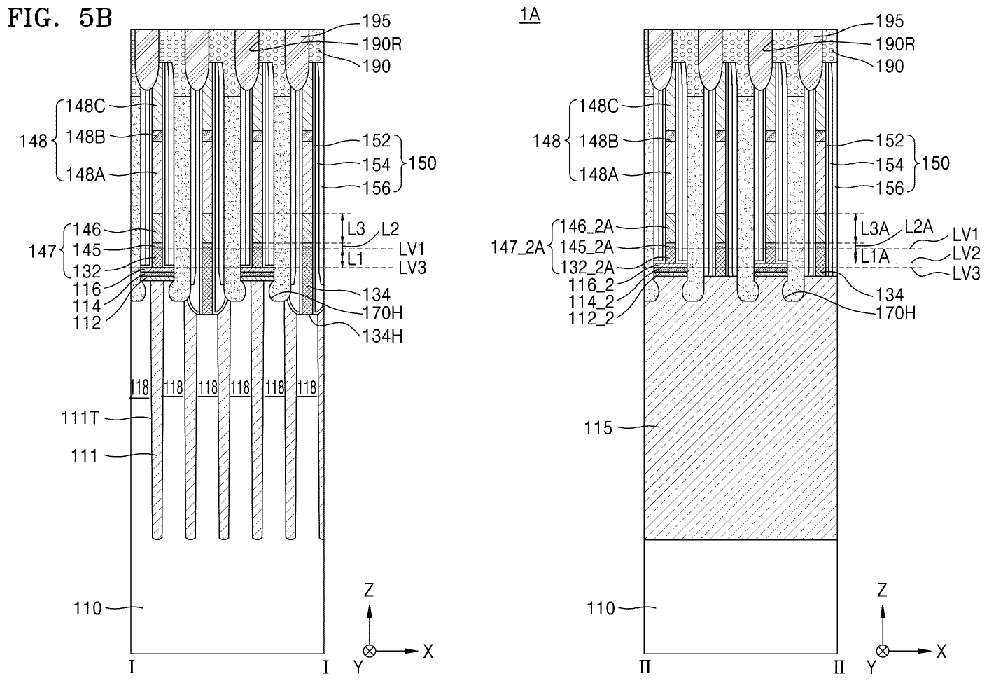

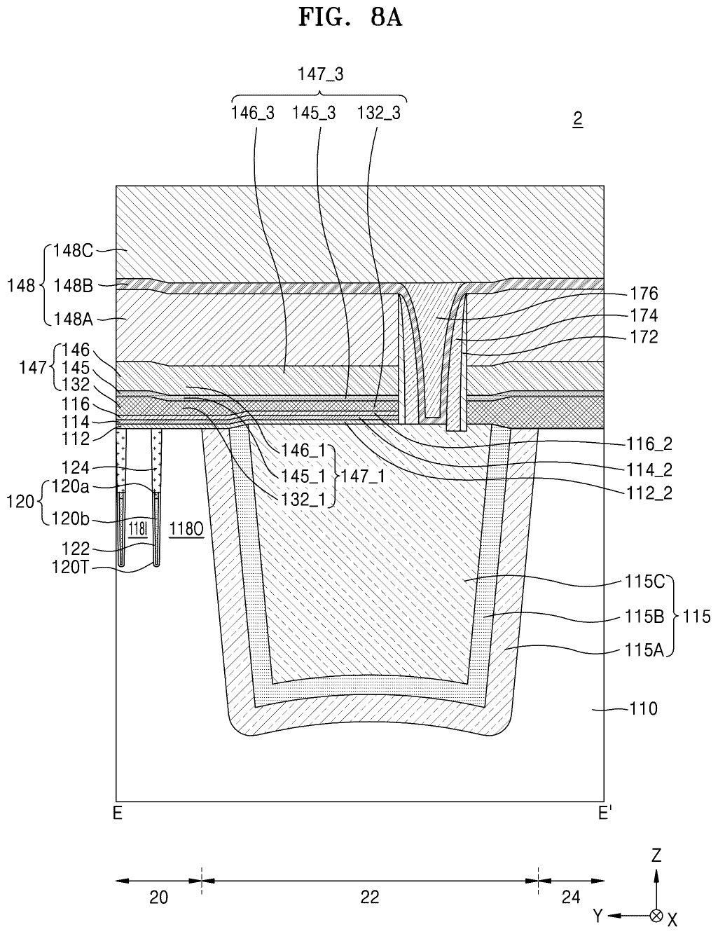

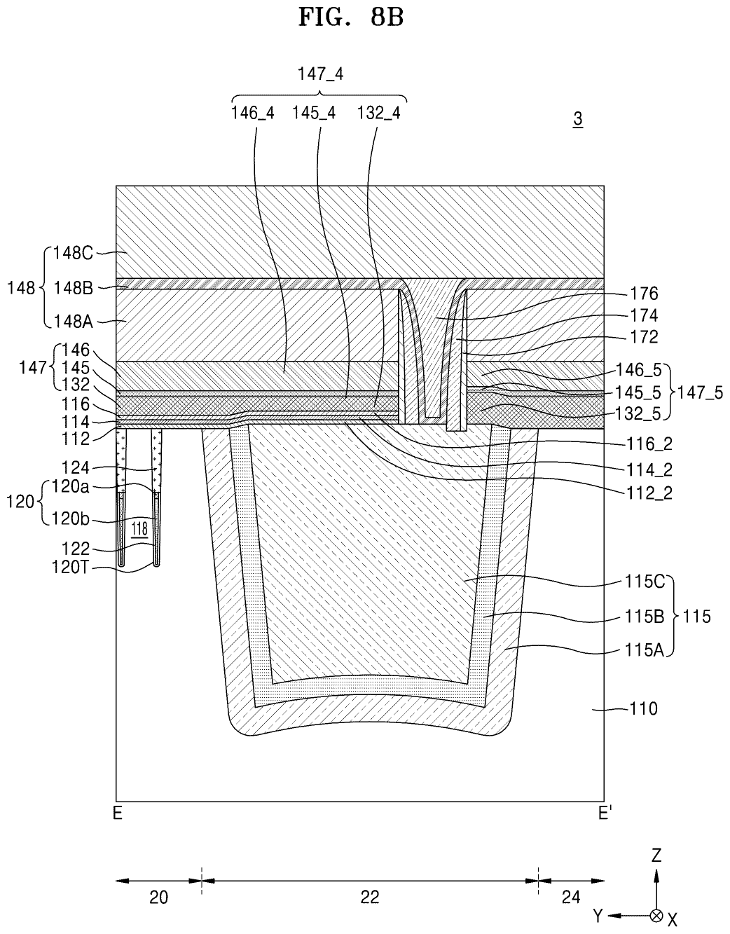

FIG. 4 is a schematic layout diagram of a region R2 of FIG. 1. FIGS. 5A, 6A, and 7A are cross-sectional views of semiconductor devices 1A, 1B, and 1C corresponding to a cross section taken along line E-E′ of FIG. 4, according to an embodiment. FIGS. 5B, 6B, and 7B are cross-sectional views taken along lines I-I and II-II of FIGS. 5A, 6A, and 7A, respectively. FIGS. 8A and 8B are cross-sectional views of semiconductor devices 2 and 3 corresponding to a cross section taken along line E-E′ of FIG. 4, according to an embodiment.

FIG. 4 illustrates a schematic layout of some components of a cell region 20, a connection region 22, and a peripheral circuit region 24. The description of the cell region 20 is as described with reference to FIG. 2.

FIGS. 5A and 5B illustrate cross-sectional views of the semiconductor device 1A according to an embodiment.

In some embodiments, a connection region isolation layer 115 may be arranged within a substrate 110 to divide the cell region 20, the connection region 22, and the peripheral circuit region 24 from one another. In detail, a region in which the connection region isolation layer 115 is arranged may be the connection region 22, and the cell region 20 and the peripheral circuit region 24 may be divided by the connection region 22. For example, the cell region 20, the connection region 22, and the peripheral circuit region 24 may be defined by the connection region isolation layer 115. In some embodiments, a plurality of word lines 120 may be arranged in the cell region 20.

In some embodiments, the connection region isolation layer 115 may include a plurality of insulating layers. For example, the connection region isolation layer 115 may include a plurality of connection region isolation layers 115A, 115B, and 115C. The connection region isolation layer 115 may include at least one of a silicon oxide layer, a silicon nitride layer, and a silicon oxynitride layer.

In some embodiments, a top surface of the connection region isolation layer 115 may be located at a higher vertical level than a top surface of the substrate 110. In detail, the top surface of the connection region isolation layer 115 may be located at a higher vertical level than the top surface of the substrate 110 in the cell region 20. In detail, the top surface of the connection region isolation layer 115 may be located at a higher vertical level than the top surface of the substrate 110 in the peripheral circuit region 24.

In some embodiments, cell insulating layers 112, 114, and 116 and connection insulating layers 112_2, 114_2, and 116_2 may be disposed on the substrate 110 and the connection region isolation layer 115. The cell insulating layers 112, 114, and 116 of FIGS. 5A and 5B may correspond to the insulating layers 112, 114, and 116 described with reference to FIGS. 2 and 3A to 3D. In some embodiments, the cell insulating layers 112, 114, and 116 and the connection insulating layers 112_2, 114_2, and 116_2 may be formed via the same process. In some embodiments, the cell insulating layers 112, 114, and 116 and the connection insulating layers 112_2, 114_2, and 116_2 may include the same material. For example, the connection insulating layers 112_2, 114_2, and 116_2 may include silicon oxide, silicon nitride, silicon oxynitride, a metallic dielectric, or a combination thereof.

In detail, the top surface of the connection region isolation layer 115 in the connection region 22 is located at a higher vertical level than the top surface of the substrate 110 in the cell region 20, and thus, the connection insulating layers 112_2, 114_2, 116_2 arranged in the connection region 22 may be located at a higher vertical level than the cell insulating layers 112, 114, and 116 arranged in the cell region 20. In other words, a top surface of each of the connection insulating layers 112_2, 114_2, and 116_2 may be located at a higher vertical level than a top surface of each of the cell insulating layers 112, 114, and 116. In other words, a bottom surface of each of the connection insulating layers 112_2, 114_2, and 116_2 may be located at a higher vertical level than a bottom surface of each of the cell insulating layers 112, 114, and 116.

In some embodiments, the cell insulating layers 112, 114, and 116 and the connection insulating layers 112_2, 114_2, and 116_2 may not be arranged in a partial region on the connection region isolation layer 115 in the connection region 22, and on the substrate 110 in the peripheral circuit region 24.

In some embodiments, a cell bit line 147 and a connection bit line 147_2A may be respectively disposed on the cell insulating layers 112, 114, and 116 in the cell region 20 and the connection insulating layers 112_2, 114_2, and 116_2 in the connection region 22. The cell bit line 147 of FIGS. 5A and 5B may correspond to the bit line 147 described with reference to FIGS. 2 and 3A to 3D. In some embodiments, the connection bit line 147_2A in the connection region 22 may be formed through the same process and subsequent process as the cell bit line 147 in the cell region 20. The cell bit line 147 and the connection bit line 147_2A may constitute a global bit line.

In some embodiments, the connection bit line 147_2A in the connection region 22 may have substantially the same structure as the cell bit line 147 in the cell region 20. In detail, the cell bit line 147 may have a stacked structure of a first cell metallic conductive pattern 145 and a second cell metallic conductive pattern 146, and the first cell metallic conductive pattern 145 and the second cell metallic conductive pattern 146 may respectively correspond to the first metallic conductive pattern 145 and the second metallic conductive pattern 146 described with reference to FIGS. 2 and 3A to 3D. For example, the connection bit line 147_2A may have a stacked structure of a first connection metallic conductive pattern 145_2A and a second connection metallic conductive pattern 146_2A.

In some embodiments, the cell bit line 147 may further include a cell conductive semiconductor pattern 132, and the cell conductive semiconductor pattern 132 may correspond to the conductive semiconductor pattern 132 described with reference to FIGS. 2 and 3A to 3D. For example, the connection bit line 147_2A may further include a connection conductive semiconductor pattern 132_2A.

In some embodiments, the connection bit line 147_2A in the connection region 22 may include the same material as the cell bit line 147 in the cell region 20. In some embodiments, the first connection metallic conductive pattern 145_2A may include titanium nitride (TiN) or Ti—Si—N (TSN), and the second connection metallic conductive pattern 146_2A may include tungsten (W), or tungsten (W) and tungsten silicide (WSiₓ). In some embodiments, the connection conductive semiconductor pattern 132_2A may include doped polysilicon.

In some embodiments, a bottom surface of the connection bit line 147_2A in the connection region 22 may be located at a higher vertical level than a bottom surface of the cell bit line 147 in the cell region 20. For example, the bottom surface of the cell bit line 147 in the cell region 20 may be located at a third vertical level LV3, and the bottom surface of the connection bit line 147_2A in the connection region 22 may be located at a second vertical level LV2 that is higher than the third vertical level LV3.

In detail, a bottom surface of the connection conductive semiconductor pattern 132_2A of the connection bit line 147_2A in the connection region 22 may be located at a higher vertical level than a bottom surface of the cell conductive semiconductor pattern 132 of the cell bit line 147 in the cell region 20. For example, the bottom surface of the cell conductive semiconductor pattern 132 in the cell region 20 may be located at the third vertical level LV3, and the bottom surface of the connection conductive semiconductor pattern 132_2A in the connection region 22 may be located at the second vertical level LV2 that is higher than the third vertical level LV3.

In detail, a top surface of the connection conductive semiconductor pattern 132_2A of the connection bit line 147_2A in the connection region 22 may be located at the same vertical level as a top surface of the cell conductive semiconductor pattern 132 of the cell bit line 147 in the cell region 20. For example, both the top surface of the cell conductive semiconductor pattern 132 in the cell region 20 and the top surface of the connection conductive semiconductor pattern 132_2A in the connection region 22 may be located at a first vertical level LV1.

In other words, a thickness L1A of the connection conductive semiconductor pattern 132_2A of the connection bit line 147_2A in the connection region 22 in a vertical direction (a Z direction) may be less than a thickness L1 of the cell conductive semiconductor pattern 132 of the cell bit line 147 in the cell region 20 in the vertical direction (the Z direction).

In some embodiments, the top surface of the connection bit line 147_2A in the connection region 22 may be located at the same vertical level as the top surface of the cell bit line 147 in the cell region 20. In detail, a top surface of the first connection metallic conductive pattern 145_2A of the connection bit line 147_2A in the connection region 22 may be located at the same vertical level as a top surface of the first cell metallic conductive pattern 145 of the cell bit line 147 in the cell region 20. In detail, a top surface of the second connection metallic conductive pattern 146_2A of the connection bit line 147_2A may be located at the same vertical level as a top surface of the second cell metallic conductive pattern 146 of the cell bit line 147 in the cell region 20. In other words, thicknesses L2A and L3A of the first connection metallic conductive pattern 145_2A and the second connection metallic conductive pattern 146_2A in the connection region 22 in the vertical direction (the Z direction) may be substantially the same as thicknesses L2 and L3 of the first cell metallic conductive pattern 145 and the second cell metallic conductive pattern 146 in the cell region 20 in the vertical direction (the Z direction), respectively.

In other words, a thickness of the connection bit line 147_2A in the connection region 22 in the vertical direction (the Z direction) may be less than a thickness of the cell bit line 147 in the cell region 20 in the vertical direction (the Z direction).

In some other embodiments, thicknesses L2A and L3A of the first connection metallic conductive pattern 145_2A and the second connection metallic conductive pattern 146_2A in the connection region 22 in the vertical direction (the Z direction) may be greater than thicknesses L2 and L3 of the first cell metallic conductive pattern 145 and the second cell metallic conductive pattern 146 in the cell region 20 in the vertical direction (the Z direction), respectively.

According to an embodiment, the semiconductor device 1A having the connection conductive semiconductor pattern 132_2A having a vertical thickness L1A that is less than a vertical thickness L1 of the cell conductive semiconductor pattern 132 may be provided. As the connection conductive semiconductor pattern 132_2A has a top surface located at the same vertical level LV1 as the cell conductive semiconductor pattern 132, the first and second connection metallic conductive patterns 145_2A and 146_2A disposed on the connection conductive semiconductor pattern 132_2A may be arranged at the same vertical level as the first and second cell metallic conductive patterns 145 and 146. In this case, in a subsequent process, deterioration of an electrical connection in the connection region 22 caused by etching the first and second connection metallic conductive patterns 145_2A and 146_2A to a higher degree than the first and second cell metallic conductive patterns 145 and 146 can be improved. In other words, the semiconductor device 1A having the first and second connection metallic conductive patterns 145_2A and 146_2A having substantially the same vertical thickness as or greater than the first and second cell metallic conductive patterns 145 and 146 may be provided. In other words, the semiconductor device 1A having improved electrical connection in the connection region 22 may be provided by embodiments.

In some embodiments, an insulating capping line 148 covering the cell bit line 147 and the connection bit line 147_2A may be disposed on the cell bit line 147 and the connection bit line 147_2A. The insulating capping line 148 may include a plurality of insulating capping lines 148A, 148B, and 148C. Each of the plurality of insulating capping lines 148A, 148B, and 148C may include silicon nitride.

In some embodiments, the insulating capping line 148 may have a bottom surface located at the same vertical level in the cell region 20 and the connection region 22. In detail, each of the plurality of insulating capping lines 148A, 148B, and 148C may have a bottom surface located at the same vertical level in the cell region 20 and the connection region 22.

In some embodiments, end spacers 172 and 174 may be disposed on the connection region isolation layer 115 in the connection region 22. The end spacers 172 and 174 may pass through portions of the connection insulating layers 112_2, 114_2, and 116_2, the connection bit line 147_2A, and the first insulating capping line 148A.

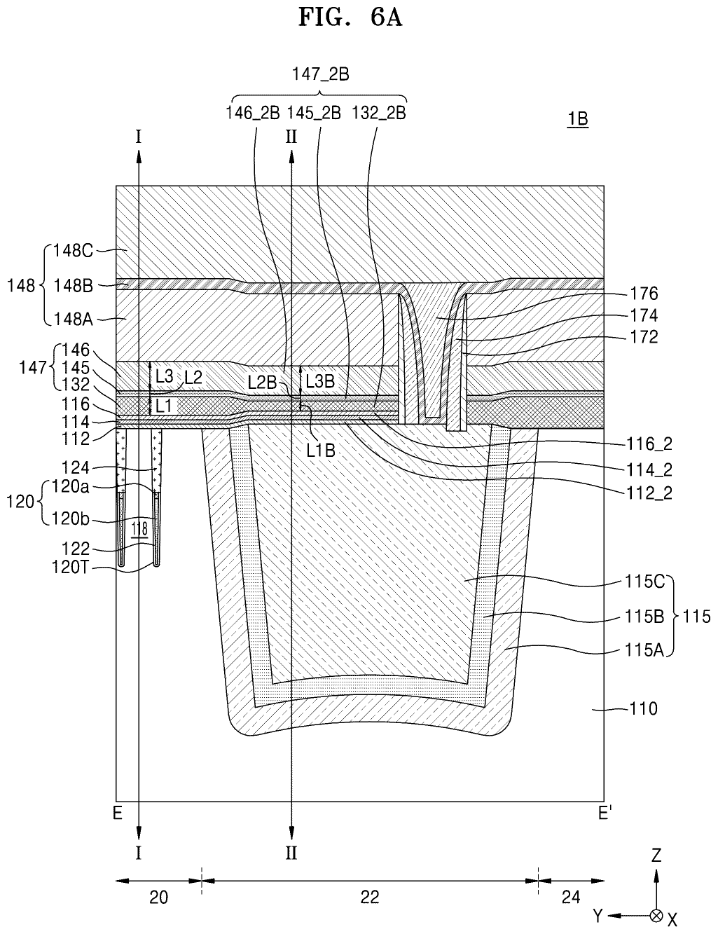

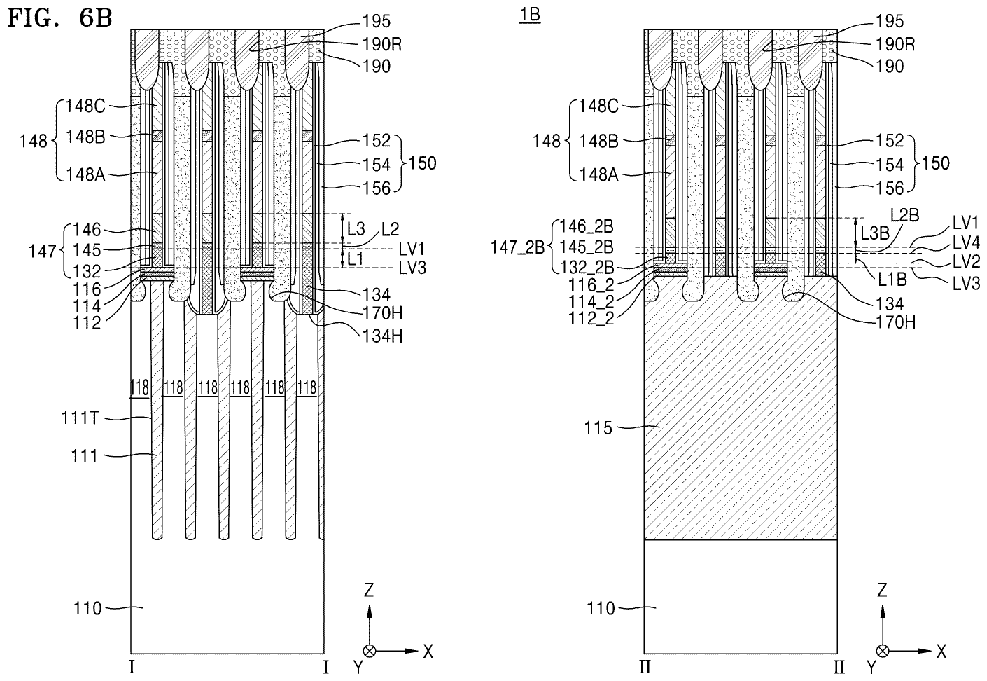

FIGS. 6A and 6B illustrate cross-sectional views of a semiconductor device 1B according to an embodiment. Hereinafter, differences from the semiconductor device 1A described with reference to FIGS. 5A and 5B will be mainly described.

In some embodiments, a connection bit line 147_2B may be disposed on connection insulating layers 112_2, 114_2, and 116_2 in a connection region 22.

In some embodiments, a bottom surface of the connection bit line 147_2B in the connection region 22 may be located at a higher vertical level than a bottom surface of a cell bit line 147 in a cell region 20. For example, the bottom surface of the cell bit line 147 in the cell region 20 may be located at a third vertical level LV3, and the bottom surface of the connection bit line 147_2B in the connection region 22 may be located at a second vertical level LV2 that is higher than the third vertical level LV3.

In detail, a bottom surface of a connection conductive semiconductor pattern 132_2B of the connection bit line 147_2B in the connection region 22 may be located at a higher vertical level than a bottom surface of a cell conductive semiconductor pattern 132 of the cell bit line 147 in the cell region 20. For example, the bottom surface of the cell conductive semiconductor pattern 132 in the cell region 20 may be located at the third vertical level LV3, and the bottom surface of the connection conductive semiconductor pattern 132_2B in the connection region 22 may be located at the second vertical level LV2 that is higher than the third vertical level LV3.

In detail, a top surface of the connection conductive semiconductor pattern 132_2B of the connection bit line 147_2B in the connection region 22 may be located at a lower vertical level than a top surface of the cell conductive semiconductor pattern 132 of the cell bit line 147 in the cell region 20. For example, the top surface of the cell conductive semiconductor pattern 132 in the cell region 20 may be located at a first vertical level LV1, and the top surface of the connection conductive semiconductor pattern 132_2B in the connection region 22 may be located at a fourth vertical level LV4 that is lower than the first vertical level LV1.

In other words, a thickness L1B of the connection conductive semiconductor pattern 132_2B of the connection bit line 147_2B in the connection region 22 in a vertical direction (a Z direction) may be less than a thickness L1 of the cell conductive semiconductor pattern 132 of the cell bit line 147 in the cell region 20 in the vertical direction (the Z direction).

In some embodiments, a top surface of the connection bit line 147_2B in the connection region 22 may be located at a lower vertical level than a top surface of the cell bit line 147 in the cell region 20. In detail, a top surface of a first connection metallic conductive pattern 145_2B of the connection bit line 147_2B in the connection region 22 may be located at a lower vertical level than a top surface of a first cell metallic conductive pattern 145 of the cell bit line 147 in the cell region 20. In detail, a top surface of a second connection metallic conductive pattern 146_2B of the connection bit line 147_2B may be located at a lower vertical level than a top surface of a second cell metallic conductive pattern 146 of the cell bit line 147 in the cell region 20. For example, vertical thicknesses L2B and L3B of the first connection metallic conductive pattern 145_2B and the second connection metallic conductive pattern 146_2B in the connection region 22 may be substantially the same as vertical thicknesses L2 and L3 of the first cell metallic conductive pattern 145 and the second cell metallic conductive pattern 146 in the cell region 20.

In other words, a thickness of the connection bit line 147_2B in the connection region 22 in the vertical direction (a Z direction) may be less than a thickness of the cell bit line 147 in the cell region 20 in the vertical direction (the Z direction).

In some other embodiments, vertical thicknesses L2B and L3B of the first connection metallic conductive pattern 145_2B and the second connection metallic conductive pattern 146_2B in the connection region 22 may be greater than vertical thicknesses L2 and L3 of the first cell metallic conductive pattern 145 and the second cell metallic conductive pattern 146 in the cell region 20.

In some embodiments, an insulating capping line 148 may have a bottom surface located at a lower vertical level in the connection region 22 than in the cell region 20. In detail, each of a plurality of insulating capping lines 148A, 148B, and 148C may have a bottom surface located at a lower vertical level in the connection region 22 than in the cell region 20.

According to an embodiment, the semiconductor device 1B having the connection conductive semiconductor pattern 132_2B having the vertical thickness L1B less than the vertical thickness L1 of the cell conductive semiconductor pattern 132 may be provided. When the first connection metallic conductive pattern 145_2B and the second connection metallic conductive pattern 146_2B of the semiconductor device 1B are arranged at a lower vertical level than the first cell metallic conductive pattern 145 and the second cell metallic conductive pattern 146, deterioration of electrical connection in the connection region 22 caused by etching the first connection metallic conductive pattern 145_2B and the second connection metallic conductive pattern 146_2B to a higher degree than the first cell metallic conductive pattern 145 and the second cell metallic conductive pattern 146 can be improved. In other words, the semiconductor device 1B having the first and second connection metallic conductive patterns 145_2B and 146_2B having substantially the same vertical thickness as or greater than the first and second cell metallic conductive patterns 145 and 146 may be provided. In other words, the semiconductor device 1B having improved electrical connection in the connection region 22 may be provided by embodiments.

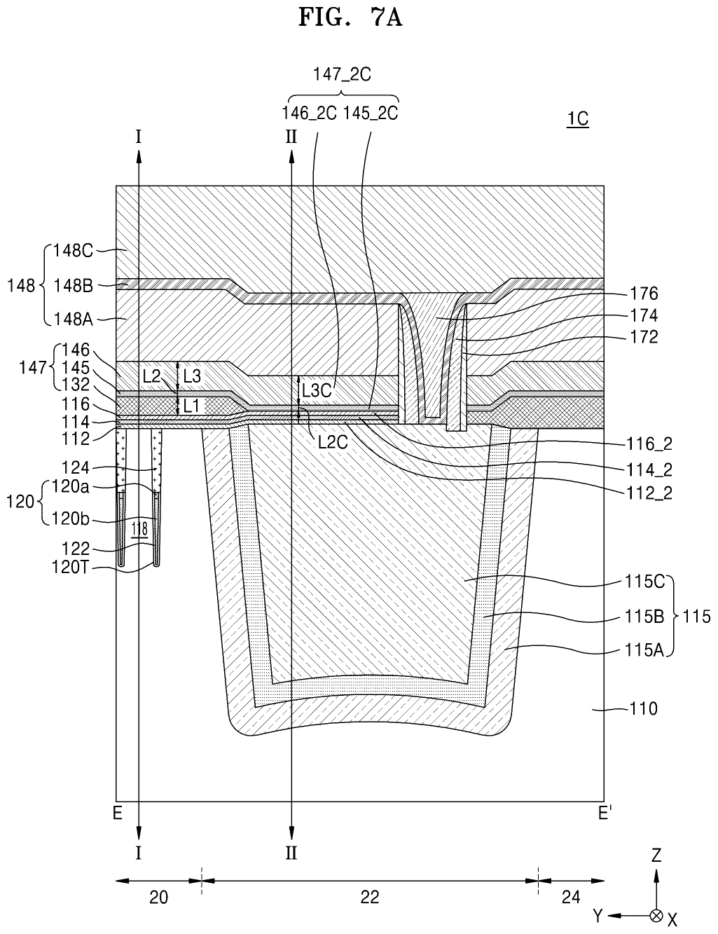

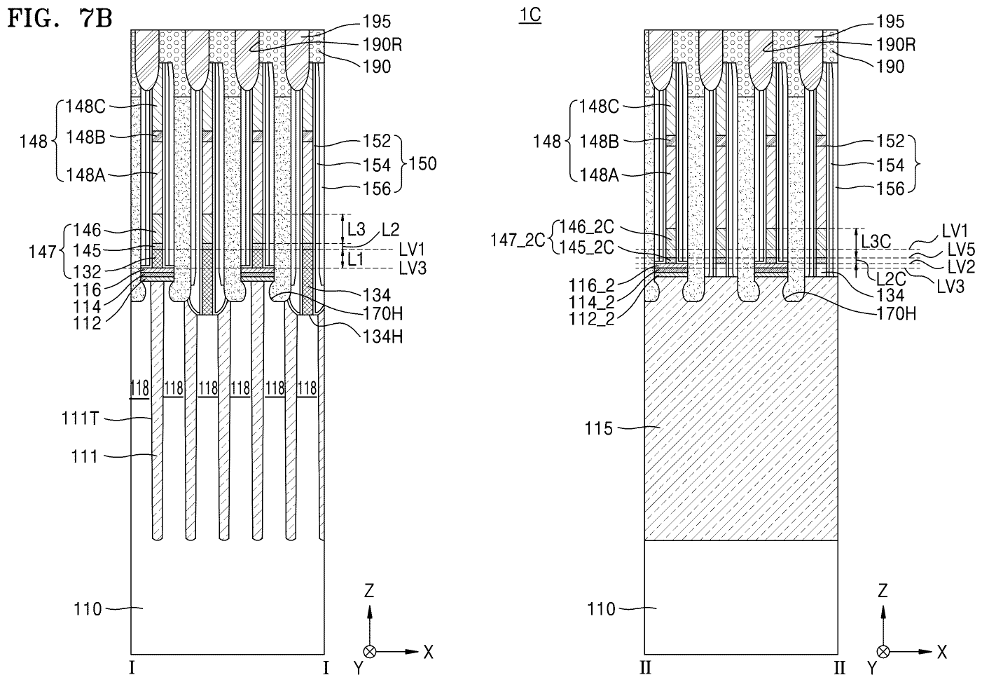

FIGS. 7A and 7B illustrate cross-sectional views of a semiconductor device 1C according to an embodiment. Differences from the semiconductor device 1A described with reference to FIGS. 5A and 5B will be mainly described.

In some embodiments, a connection bit line 147_2C may be disposed on connection insulating layers 112_2, 114_2, and 116_2 in a connection region 22. Unlike in the semiconductor device 1A, the connection bit line 147_2C of the semiconductor device 1C may not include a connection conductive semiconductor pattern disposed on the connection insulating layers 112_2, 114_2, and 116_2. In other words, the connection bit line 147_2C of the semiconductor device 1C disposed in the connection region 22 may include a first connection metallic conductive pattern 145_2C and a second connection metallic conductive pattern 146_2C directly disposed on the connection insulating layers 112_2, 114_2, and 116_2. In detail, the first connection metallic conductive pattern 145_2C may directly contact and be disposed on the connection insulating layers 112_2, 114_2, and 116_2. In other words, at least a portion of a bottom surface of the first connection metallic conductive pattern 145_2C may be located at the same vertical level as top surface of the connection insulating layers 112_2, 114_2, and 116_2.

In some embodiments, a bottom surface of the connection bit line 147_2C in the connection region 22 may be located at a higher vertical level than a bottom surface of the cell bit line 147 in a cell region 20. For example, the bottom surface of the cell bit line 147 in the cell region 20 may be located at a third vertical level LV3, and the bottom surface of the connection bit line 147_2C in the connection region 22 may be located at a second vertical level LV2 that is higher than the third vertical level LV3.

In detail, the bottom surface of the first connection metallic conductive pattern 145_2C of the connection bit line 147_2C in the connection region 22 may be located at a higher vertical level than a bottom surface of a cell conductive semiconductor pattern 132 of the cell bit line 147 in the cell region 20. For example, the bottom surface of the cell conductive semiconductor pattern 132 in the cell region 20 may be located at the third vertical level LV3, and the bottom surface of the first connection metallic conductive pattern 145_2C in the connection region 22 may be located at the second vertical level LV2 that is higher than the third vertical level LV3.

In detail, while a bottom surface of a first cell metallic conductive pattern 145 of the cell bit line 147 in the cell region 20 is located at a first vertical level LV1, the bottom surface of the first connection metallic conductive pattern 145_2C of the connection bit line 147_2C in the connection region 22 may be located at the second vertical level LV2 that is lower than the first vertical level LV1. In detail, a top surface of the first connection metallic conductive pattern 145_2C of the connection bit line 147_2C in the connection region 22 may be located at a fifth vertical level LV5 that is lower than the first vertical level LV1.

In some embodiments, a top surface of the connection bit line 147_2C in the connection region 22 may be located at a lower vertical level than a top surface of the cell bit line 147 in the cell region 20. In detail, the top surface of the first connection metallic conductive pattern 145_2C of the connection bit line 147_2C in the connection region 22 may be located at a lower vertical level than a top surface of the first cell metallic conductive pattern 145 of the cell bit line 147 in the cell region 20. In detail, a top surface of the second connection metallic conductive pattern 146_2C of the connection bit line 147_2C may be located at a lower vertical level than a top surface of a second cell metallic conductive pattern 146 of the cell bit line 147 in the cell region 20. For example, thicknesses L2C and L3C of the first connection metallic conductive pattern 145_2C and the second connection metallic conductive pattern 146_2C in the connection region 22 in a vertical direction (a Z direction) may be substantially the same as thicknesses L2 and L3 of the first cell metallic conductive pattern 145 and the second cell metallic conductive pattern 146 in the cell region 20 in the vertical direction (the Z direction).

In other words, a thickness of the connection bit line 147_2C in the connection region 22 in the vertical direction (the Z direction) may be less than a thickness of the cell bit line 147 in the cell region 20 in the vertical direction (the Z direction).

In some other embodiments, thicknesses L2C and L3C of the first connection metallic conductive pattern 145_2C and the second connection metallic conductive pattern 146_2C in the connection region 22 in a vertical direction (a Z direction) may be greater than thicknesses L2 and L3 of the first cell metallic conductive pattern 145 and the second cell metallic conductive pattern 146 in the cell region 20 in the vertical direction (the Z direction).

In some embodiments, an insulating capping line 148 may have a bottom surface located at a lower vertical level in the connection region 22 than in the cell region 20. In detail, each of a plurality of insulating capping lines 148A, 148B, and 148C may have a bottom surface located at a lower vertical level in the connection region 22 than in the cell region 20.

Referring to FIGS. 5A, 5B, 6A, 6B, 7A, and 7B together, the semiconductor devices 1A, 1B, and 1C may respectively include the connection bit lines 147_2A, 147_2B, and 147_2C having different thicknesses in the vertical direction (the Z direction). In detail, the semiconductor device 1A and the semiconductor device 1B may respectively include the connection conductive semiconductor pattern 132_2A and the connection conductive semiconductor pattern 132_2B having different thicknesses in the vertical direction (the Z direction), and the semiconductor device 1C may not include a connection conductive semiconductor pattern. In detail, thicknesses of the first connection metallic conductive patterns 145_2A, 145_2B, and 145_2C of the semiconductor devices 1A, 1B, and 1C in the vertical direction (the Z direction) may be substantially the same as one another, and thicknesses of the second connection metallic conductive patterns 146_2A, 146_2B, and 146_2C in the vertical direction (the Z direction) may be substantially the same as one another.

For example, the thickness of the connection bit line 147_2B of the semiconductor device 1B in the vertical direction (the Z direction) may be less than the thickness of the connection bit line 147_2A of the semiconductor device 1A in the vertical direction (the Z direction). For example, the thickness of the connection bit line 147_2C of the semiconductor device 1C in the vertical direction (the Z direction) may be less than the thickness of the connection bit line 147_2B of the semiconductor device 1B in the vertical direction (Z direction).

For example, the semiconductor device 1A may include the connection conductive semiconductor pattern 132_2A having the thickness L1A in the vertical direction (the Z direction), and the semiconductor device 1B may include the connection conductive semiconductor pattern 132_2B having the thickness L1B in the vertical direction (Z direction), which is less than the thickness L1A.

For example, the thickness L2A of the first connection metallic conductive pattern 145_2A of the semiconductor device 1A in the vertical direction (the Z direction), the thickness L2B of the first connection metallic conductive pattern 145_2C of the semiconductor device 1B in the vertical direction (the Z direction), and the thickness L2C of the first connection metallic conductive pattern 145_2C of the semiconductor device 1C in the vertical direction (the Z direction) may be substantially the same as one another. Similarly, the thickness L3A of the second connection metallic conductive pattern 146_2A in the vertical direction (the Z direction), the thickness L3B of the second connection metallic conductive pattern 146_2B in the vertical direction (the Z direction), and the thickness L3C the second connection metallic conductive pattern 146_2C in the vertical direction (the Z direction) may be substantially the same as one another.

Continuously referring to FIGS. 5A, 5B, 6A, 6B, 7A, and 7B together, the bottom surfaces of the connection bit lines 147_2A, 147_2B, and 147_2C of the semiconductor devices 1A, 1B, and 1C may be located at the same vertical level LV2. In contrast, the top surfaces of the connection bit lines 147_2A, 147_2B, and 147_2C of the semiconductor devices 1A, 1B, and 1C may be located at different vertical levels. In detail, the connection bit line 147_2A, the connection bit line 147_2B, and the connection bit line 147_2C may be located at higher vertical levels in that order.

In detail, the top surface of the connection conductive semiconductor pattern 132_2A of the semiconductor device 1A may be located at the first vertical level LV1, and the top surface of the connection conductive semiconductor pattern 132_2B of the semiconductor device 1B may be located at the fourth vertical level LV4 that is lower than the first vertical level LV1.

In detail, the first connection metallic conductive pattern 145_2A of the semiconductor device 1A, the first connection metallic conductive pattern 145_2B of the semiconductor device 1B, and the first connection metallic conductive pattern 145_2C of the semiconductor device 1C may be located at different vertical levels. For example, the first connection metallic conductive pattern 145_2A, the first connection metallic conductive pattern 145_2B, and the first connection metallic conductive pattern 145_2C may be located at higher vertical levels in that order. Similarly, the second connection metallic conductive pattern 146_2A, the second connection metallic conductive pattern 146_2B, and the second connection metallic conductive pattern 146_2C may be located at different vertical levels, and the second connection metallic conductive pattern 146_2A, the second connection metallic conductive pattern 146_2B, and the second connection metallic conductive pattern 146_2C may be located at higher vertical levels in that order.

FIG. 8A illustrates a cross-sectional view of a semiconductor device 2 according to an embodiment. Differences from the semiconductor device 1B described with reference to FIGS. 6A and 6B will be mainly described.

In some embodiments, a plurality of active regions 118 arranged within a substrate 110 in a cell region 20 may include an outer active region 118O and an inner active region 118I. In detail, the outer active region 118O may be an active region adjacent to a connection region isolation layer 115, from among the plurality of active regions 118. In detail, the inner active region 118I may be an active region spaced apart from the connection region isolation layer 115 with the outer active region 1180 therebetween, except for the outer active region 118O from among the plurality of active regions 118. The plurality of active regions 118 may include at least one inner active region 118I. The plurality of active regions 118 may include a plurality of inner active regions 118I.

In some embodiments, a cell bit line 147 disposed on the substrate 110 in the cell region 20 may include a portion 147_1 disposed on the outer active region 118O. In detail, a cell conductive semiconductor pattern 132 may include a portion 132_1 disposed on the outer active region 118O. In detail, a first cell metallic conductive pattern 145 may include a portion 145_1 disposed on the outer active region 118O. In detail, a second cell metallic conductive pattern 146 may include a portion 146_1 disposed on the outer active region 118O.

In some embodiments, a top surface of the portion 147_1 of the cell bit line 147 disposed on the outer active region 118O may have a lower vertical level than a top surface of a remaining portion disposed on the inner active region 118I. A bottom surface of the portion 147_1 of the cell bit line 147 disposed on the outer active region 118O may have the same vertical level as a bottom surface of the remaining portion disposed on the inner active region 118I.

In some embodiments, the top surface of the portion 147_1 of the cell bit line 147 disposed on the outer active region 118O in the cell region 20 may have the same vertical level as a top surface of a connection bit line 147_3 in a connection region 22. The bottom surface of the portion 147_1 of the cell bit line 147 disposed on the outer active region 118O in the cell region 20 may have a lower vertical level than a bottom surface of the connection bit line 147_3 in the connection region 22.

In detail, a top surface of the portion 132_1 of the cell conductive semiconductor pattern 132 disposed on the outer active region 118O in the cell region 20 may have a vertical level that is lower than the top surface of the remaining portion disposed on the inner active region 118I and is the same as a top surface of a connection conductive semiconductor pattern 132_3 in the connection region 22. A bottom surface of the portion 132_1 of the cell conductive semiconductor pattern 132 disposed on the outer active region 118O in the cell region 20 may have a vertical level that is the same as the bottom surface of the remaining portion disposed on the inner active region 118I and is lower than a bottom surface of the connection conductive semiconductor pattern 132_3 in the connection region 22.

In detail, a top surface of the portion 145_1 of the first cell metallic conductive pattern 145 disposed on the outer active region 118O in the cell region 20 may have a vertical level that is lower than the top surface of the remaining portion disposed on the inner active region 118I and is the same as a top surface of a first connection metallic conductive pattern 145_3 in the connection region 22. A bottom surface of the portion 145_1 of the first cell metallic conductive pattern 145 disposed on the outer active region 118O in the cell region 20 may have a vertical level that is lower than the bottom surface of the remaining portion disposed on the inner active region 118I and is the same as a bottom surface of the first connection metallic conductive pattern 145_3 in the connection region.

In detail, a top surface of the portion 146_1 of the second cell metallic conductive pattern 146 disposed on the outer active region 118O in the cell region 20 may have a vertical level that is lower than the top surface of the remaining portion disposed on the inner active region 118I and is the same as a top surface of a second connection metallic conductive pattern 146_3 in the connection region 22. A bottom surface of the portion 146_1 of the second cell metallic conductive pattern 146_1 disposed on the outer active region 118O in the cell region 20 may have a vertical level that is lower than the bottom surface of the remaining portion disposed on the inner active region 118I and is the same as a bottom surface of the second connection metallic conductive pattern 146_3 in the connection region 22.

FIG. 8B illustrates a cross-sectional view of a semiconductor device 3 according to an embodiment. Differences from the semiconductor device 1A described with reference to FIGS. 5A and 5B will be mainly described.

In some embodiments, a connection region 22 may include a portion adjacent to a peripheral circuit region 24 and a portion adjacent to a cell region 20. From a cross-sectional point of view, the portion adjacent to the peripheral circuit region 24 may be located opposite to the portion adjacent to the cell region 20 with respect to end spacers 172 and 174. A connection conductive semiconductor pattern 132_4 may include a portion 132_5 adjacent to the peripheral circuit region 24.

In some embodiments, connection insulating layers 112_2, 114_2, and 116_2 may not be disposed on a connection region isolation layer 115 of the portion adjacent to the peripheral circuit region 24. Accordingly, the portion 132_5 of the connection conductive semiconductor pattern 132_4 disposed on the connection region isolation layer 115 of the portion of the connection region 22 adjacent to the peripheral circuit region 24 may be arranged in contact with the connection region isolation layer 115. In other words, a bottom surface of the portion 132_5 of the connection conductive semiconductor pattern 132_4 may be located at the same vertical level as a top surface of the connection region isolation layer 115.

In some embodiments, a top surface of the portion 132_5 of the connection conductive semiconductor pattern 132_4 adjacent to the peripheral circuit region 24 may be located at a higher vertical level than a top surface of a cell conductive semiconductor pattern 132. In some embodiments, the top surface of the portion 132_5 of the connection conductive semiconductor pattern 132_4 may be located at a higher vertical level than a top surface of a remaining portion adjacent to the cell region 20.

In some embodiments, a top surface of a portion 145_5 of a first connection metallic conductive pattern 145_4 disposed in the portion adjacent to the peripheral circuit region 24 may be located at a higher vertical level than a top surface of a first cell metallic conductive pattern 145. In some embodiments, the top surface of the portion 145_5 of the first connection metallic conductive pattern 145_4 may be located at a higher vertical level than the top surface of the remaining portion adjacent to the cell region 20.

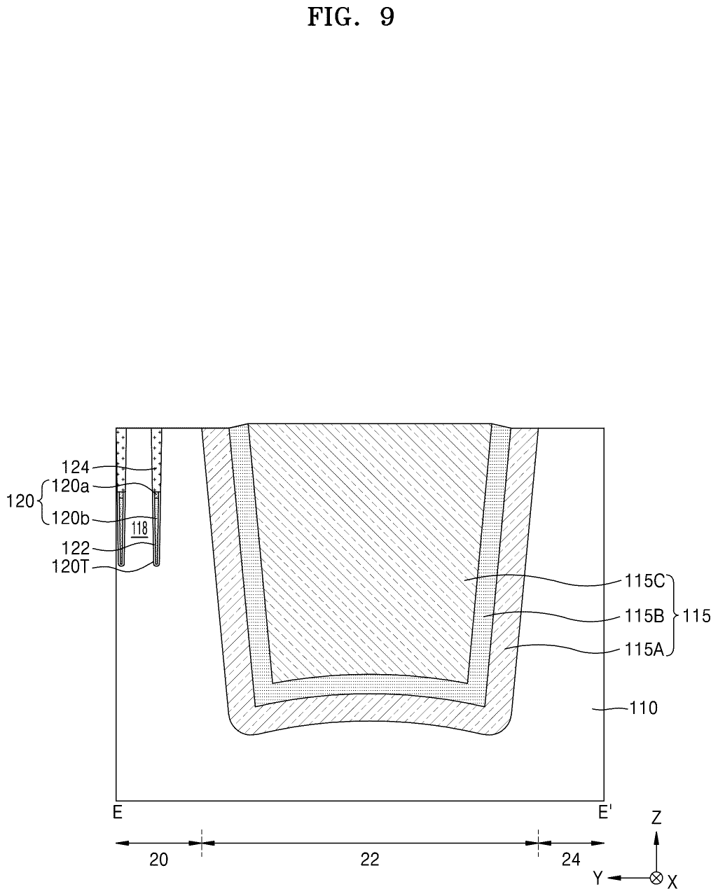

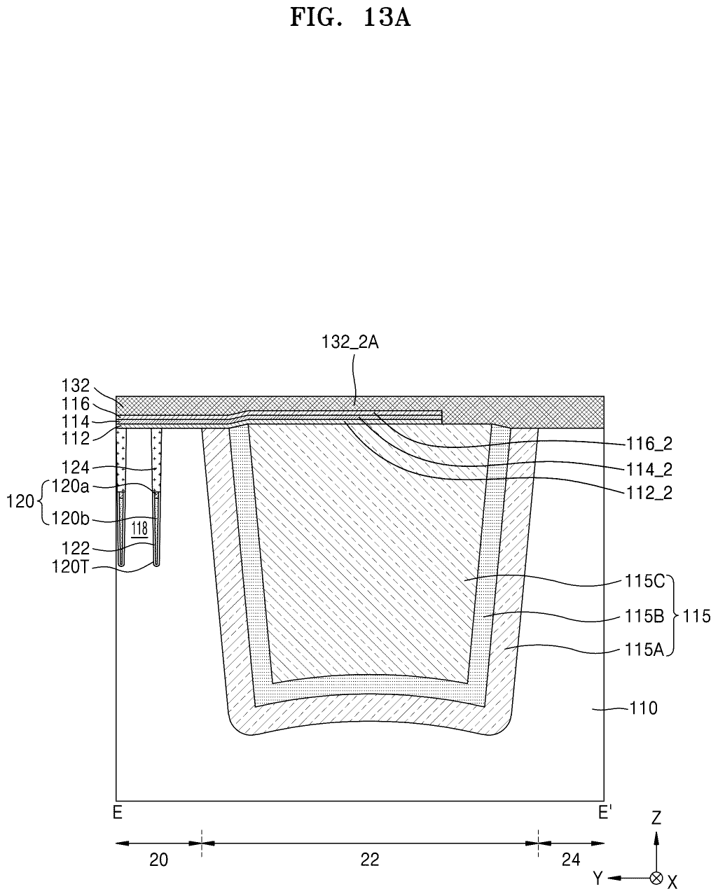

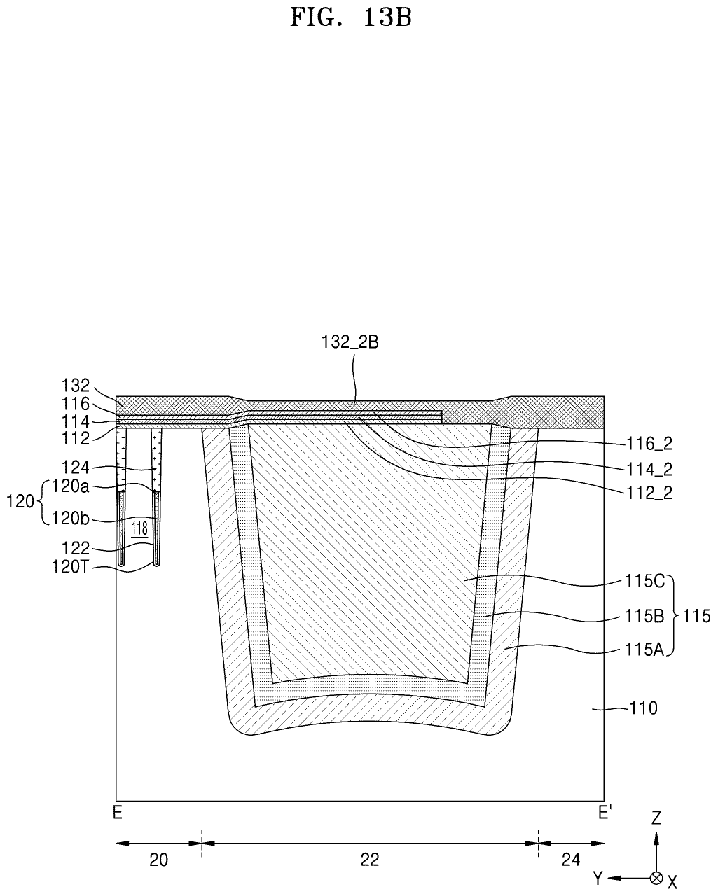

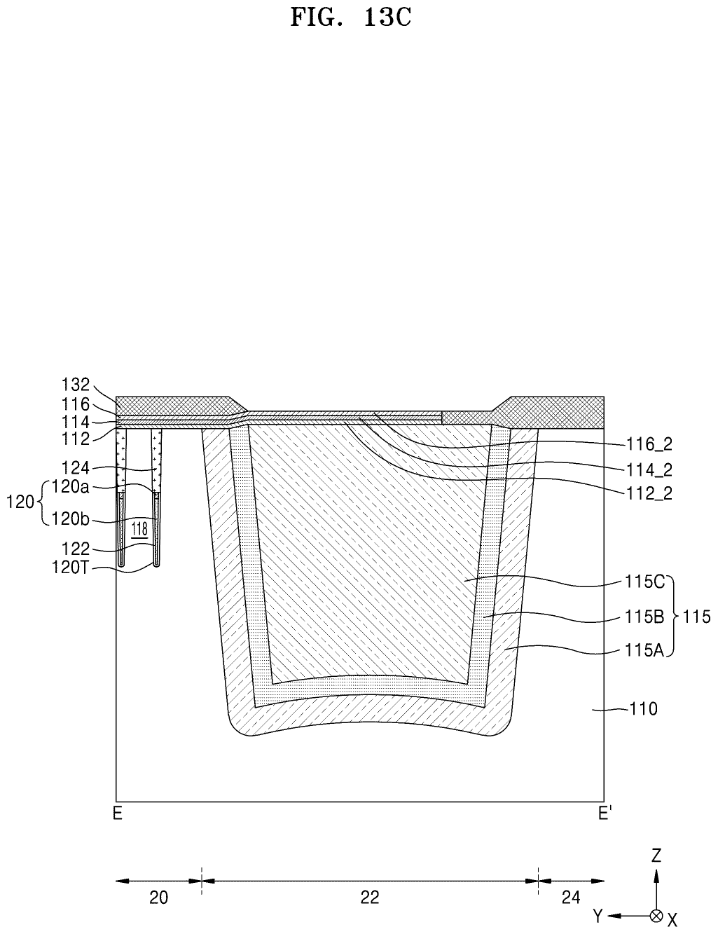

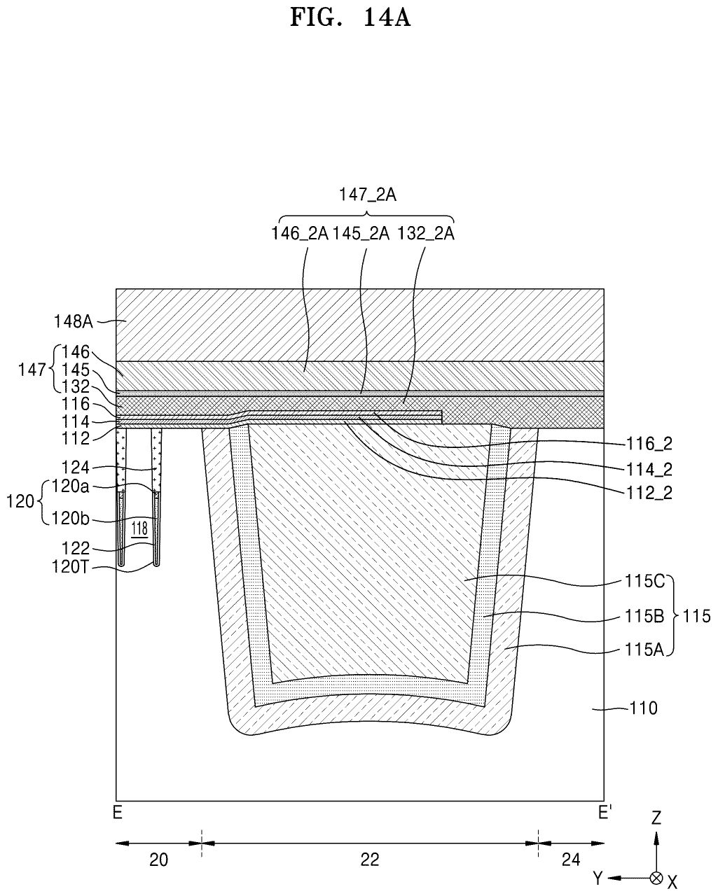

FIGS. 9 to 16C are cross-sectional views illustrating a method of manufacturing the semiconductor devices 1A, 1B, and 1C, according to an embodiment. In detail, FIGS. 9 to 12 are cross-sectional views common in a method of manufacturing the semiconductor devices 1A, 1B, and 1C, and FIGS. 13A to 16A, 13B to 16B, and 13C to 16C are cross-sectional views of a method of manufacturing the semiconductor device 1A, the semiconductor device 1B, and the semiconductor device 1C, respectively.

Referring to FIG. 9, a connection region isolation layer 115 may be arranged within a substrate 110 to define a cell region 20, a connection region 22, and a peripheral circuit region 24.

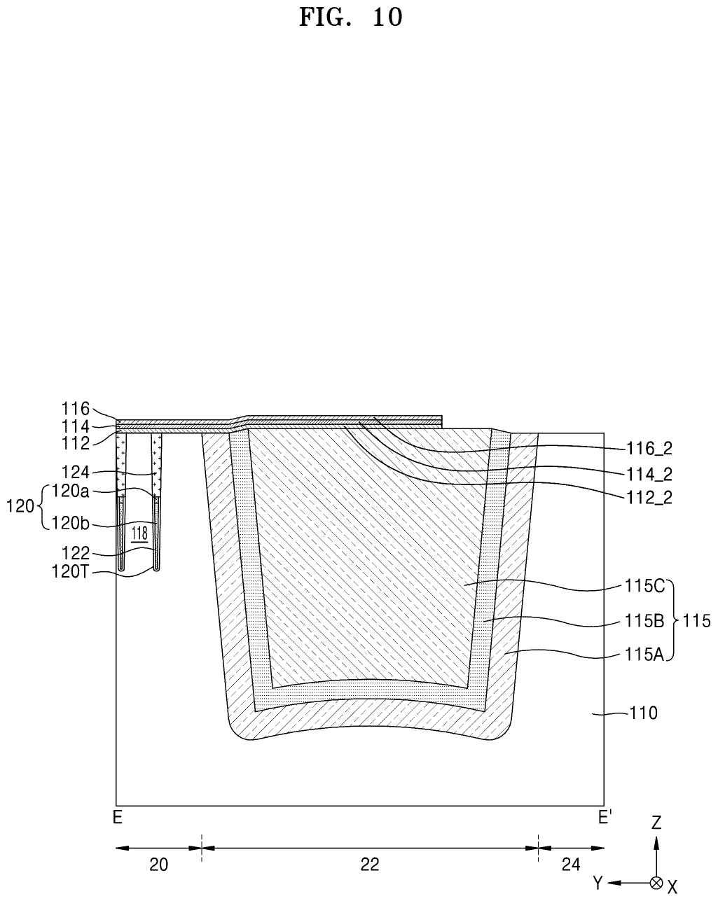

Referring to FIG. 10, an insulating layer may be disposed on the substrate 110 in the cell region 20 and the connection region 22. In detail, cell insulating layers 112, 114, and 116 may be disposed on the substrate 110 in the cell region 20, and connection insulating layers 112_2, 114_2, and 116_2 may be disposed on the connection region isolation layer 115 in the connection region 22. In some embodiments, an insulating layer may not be disposed in a partial region on the connection region isolation layer 115 in the connection region 22, and on the substrate 110 in the peripheral circuit region 24. In some embodiments, the connection insulating layers 112_2, 114_2, and 116_2 on the connection region isolation layer 115 in the connection region 22 may be arranged at a higher vertical level than the cell insulating layers 112, 114, and 116 on the substrate 110 in the cell region 20.

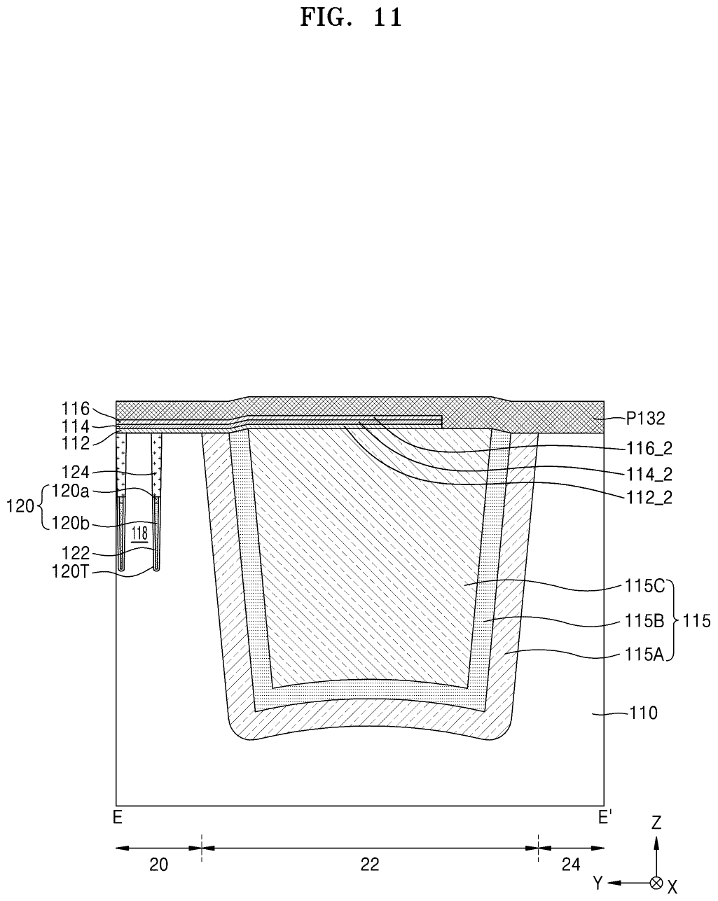

Referring to FIG. 11, a pre-conductive semiconductor pattern P132 may be disposed on the substrate 110. In detail, in the cell region 20, the pre-conductive semiconductor pattern P132 may be disposed on the cell insulating layers 112, 114, and 116. In detail, in the connection region 22, the pre-conductive semiconductor pattern P132 may be disposed on the connection insulating layers 112_2, 114_2, and 116_2 and the connection region isolation layer 115. In detail, in the peripheral circuit region 24, the pre-conductive semiconductor pattern P132 may be disposed on the substrate 110.

In some embodiments, the pre-conductive semiconductor pattern P132 arranged in the connection region 22 may have a top surface and a bottom surface having a higher vertical level than the pre-conductive semiconductor pattern P132 arranged in the cell region 20 and the peripheral circuit region 24.

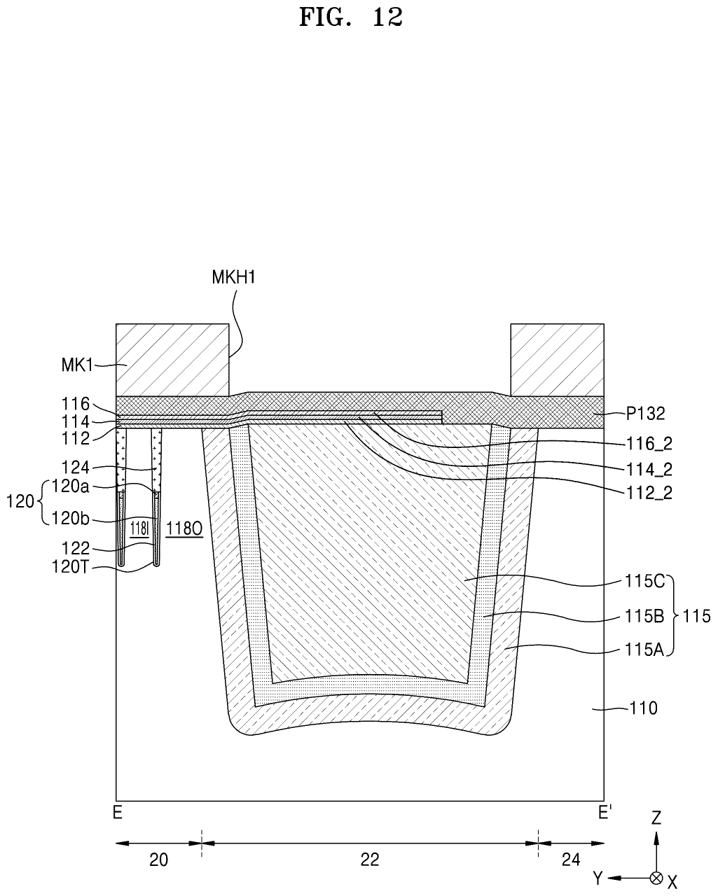

Referring to FIG. 12, a first mask MK1 may be disposed on the pre-conductive semiconductor pattern P132. The first mask MK1 may include a first mask hole MKH1 exposing a partial region of the pre-conductive semiconductor pattern P132. The first mask hole MKH1 may expose a portion of the pre-conductive semiconductor pattern P132 in the connection region 22. In detail, the first mask hole MKH1 may expose a portion of the pre-conductive semiconductor pattern P132 in the connection region 22, which is located at a high vertical level.

In some embodiments, although not illustrated, the first mask hole MKH1 may expose a portion of the pre-conductive semiconductor pattern P132 in the connection region 22, which is located at a high vertical level and a portion of the pre-conductive semiconductor pattern P132 in the cell region 20. In detail, the portion of the pre-conductive semiconductor pattern P132 in the cell region 20, which is exposed by the first mask hole MKH1, may include a portion of the pre-conductive semiconductor pattern P132 disposed on an outer active region 118O.

Referring to FIGS. 13A, 13B, and 13C, the portion of the pre-conductive semiconductor pattern P132 of FIG. 12, which is exposed by the first mask hole MKH1 of FIG. 12, may be etched to form a cell conductive semiconductor pattern 132 and connection conductive semiconductor patterns 132_2A and 132_2B.

In some embodiments, as illustrated in FIG. 13A, the portion of the pre-conductive semiconductor pattern P132 exposed by the first mask hole MKH1 may be etched to have the same vertical level as the cell conductive semiconductor pattern 132 in the cell region 20. In other words, a top surface of the connection conductive semiconductor pattern 132_2A may have the same vertical level as a top surface of the cell conductive semiconductor pattern 132.

In some embodiments, as illustrated in FIG. 13B, the portion of the pre-conductive semiconductor pattern P132 exposed by the first mask hole MKH1 may be etched to have a lower vertical level than the cell conductive semiconductor pattern 132 in the cell region 20. In other words, a top surface of the connection conductive semiconductor pattern 132_2B may have a lower vertical level than a top surface of the cell conductive semiconductor pattern 132.

In some embodiments, as illustrated in FIG. 13C, all of the pre-conductive semiconductor pattern P132 exposed by the first mask hole MKH1 may be etched. In other words, all of the pre-conductive semiconductor pattern P132 may be etched so that the connection insulating layers 112_2, 114_2, and 116_2 are exposed.

In some embodiments, although not illustrated, when the first mask hole MKH1 further exposes a portion of the pre-conductive semiconductor pattern P132 disposed on the outer active region 118O, the portion exposed by the first mask hole MKH1 may be etched. In other words, the portion of the cell conductive semiconductor pattern disposed on the outer active region 118O may have a top surface located at a lower vertical level than a remaining portion.

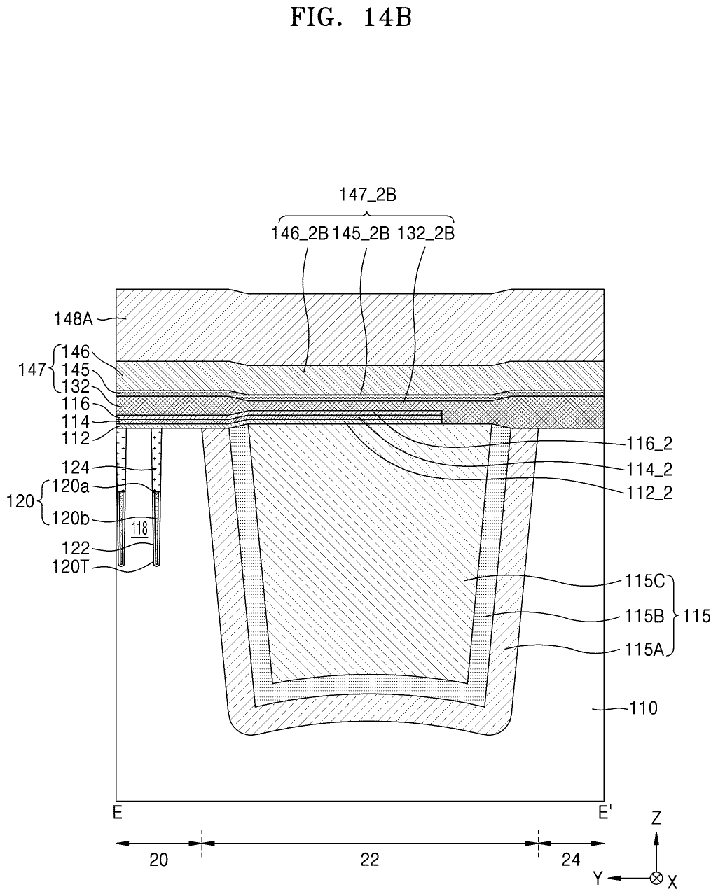

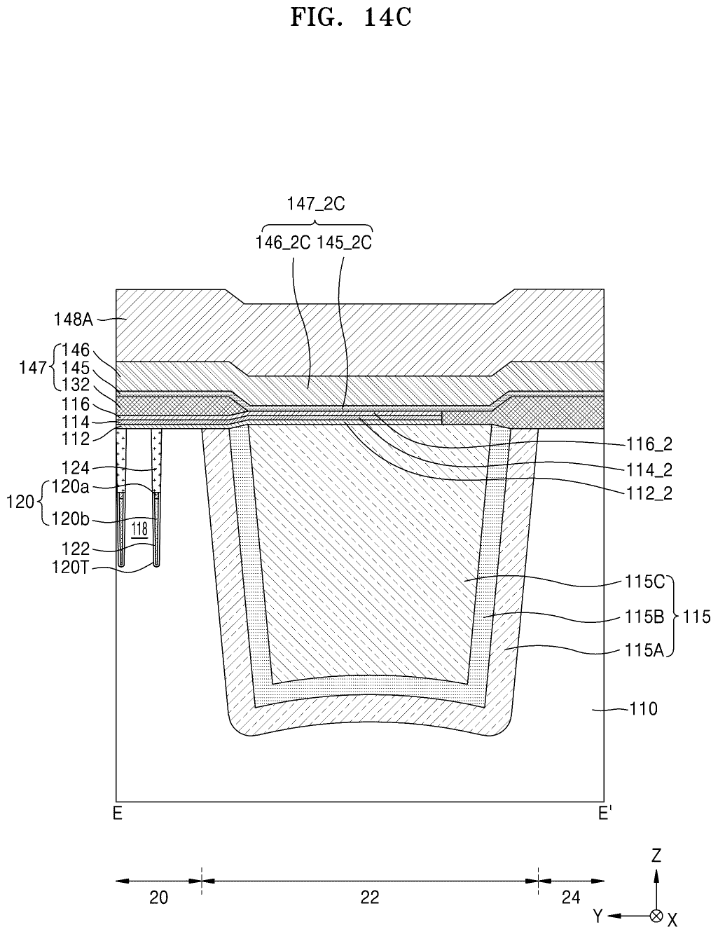

Referring to FIGS. 14A, 14B, and 14C, a cell bit line 147 and connection bit lines 147_2A, 147_2B, and 147_2C may be formed by arranging cell metallic conductive patterns 145 and 146, and connection metallic conductive patterns 145_2A, 146_2A, 145_2B, 146_2B, 145_2C, and 146_2C. In detail, the first cell metallic conductive pattern 145 and the first connection metallic conductive patterns 145_2A, 145_2B, and 145_2C may have the same vertical thickness. In detail, the second cell metallic conductive pattern 146 and the second connection metallic conductive patterns 146_2A, 146_2B, and 146_2C may have the same vertical thickness. A first insulating capping line 148A may be disposed on the cell bit line 147 and the connection bit lines 147_2A, 147_2B, and 147_2C.

In some embodiments, as illustrated in FIG. 14A, the first connection metallic conductive pattern 145_2A may have the same vertical level as the first cell metallic conductive pattern 145. The second connection metallic conductive pattern 146_2A may have the same vertical level as the second cell metallic conductive pattern 146. The first insulating capping line 148A may have a bottom surface arranged at the same vertical level in the cell region 20 and the connection region 22.

In some embodiments, as illustrated in FIG. 14B, the first connection metallic conductive pattern 145_2B may have a lower vertical level than the first cell metallic conductive pattern 145. The second connection metallic conductive pattern 146_2B may have a lower vertical level than the second cell metallic conductive pattern 146. The first insulating capping line 148A may have a bottom surface arranged at a lower vertical level in the connection region 22 than in the cell region 20.

In some embodiments, as illustrated in FIG. 14C, the first connection metallic conductive pattern 145_2C may have a lower vertical level than the first cell metallic conductive pattern 145. The second connection metallic conductive pattern 146_2C may have a lower vertical level than the second cell metallic conductive pattern 146. The first insulating capping line 148A may have a bottom surface arranged at a lower vertical level in the connection region 22 than in the cell region 20.

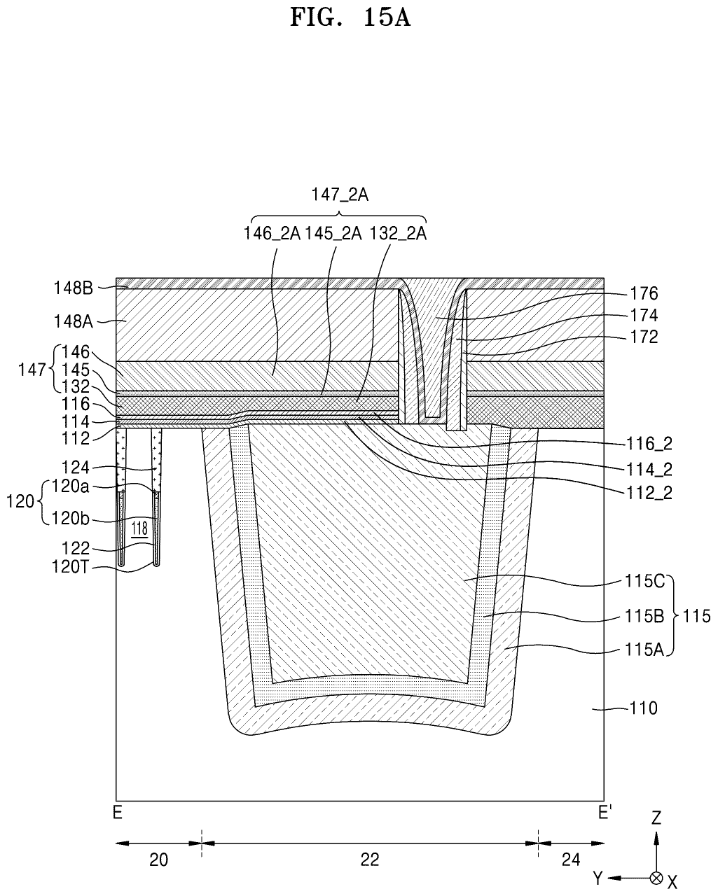

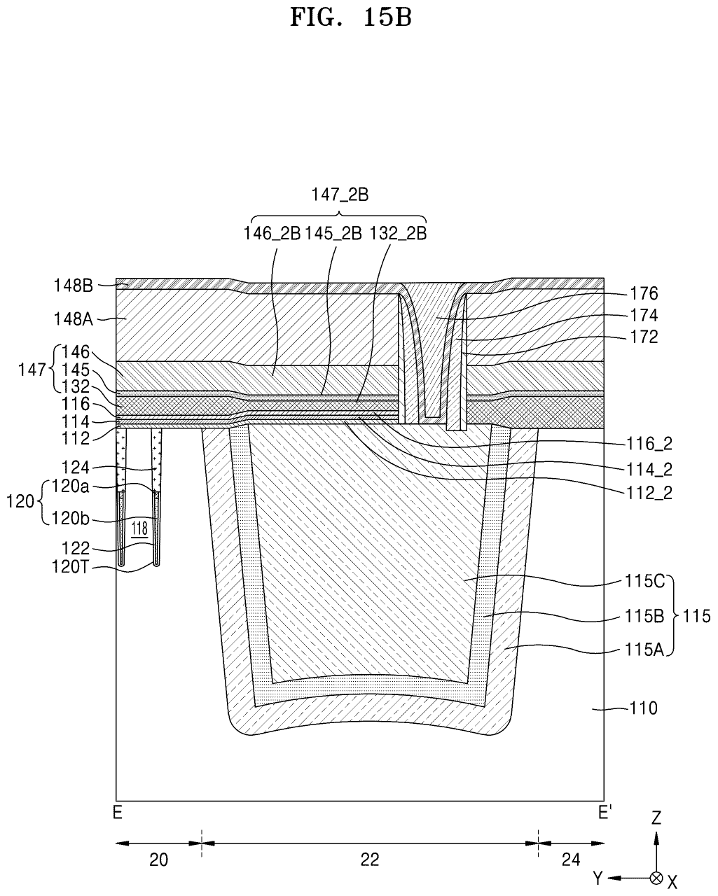

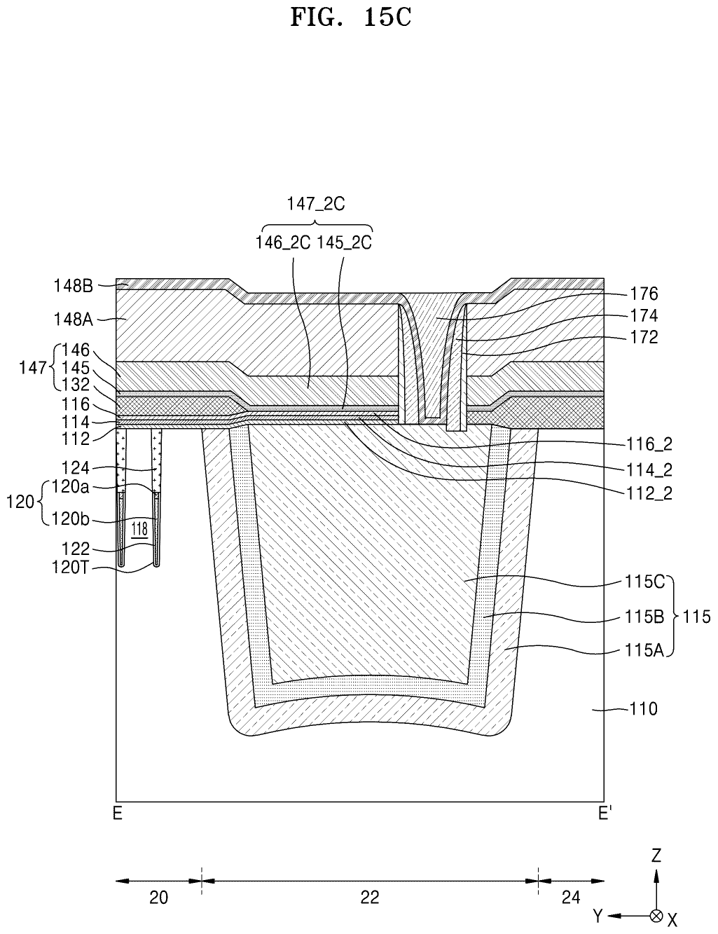

Referring to FIGS. 15A, 15B, and 15C, a first end spacer 172 and a second end spacer 174 may be formed by etching portions of the first insulating capping line 148A and the connection bit lines 147_2A, 147_2B, and 147_2C, and then a second insulating capping line 148B covering the first insulating capping line 148A and the second end spacer 17B may be formed. The first end spacer 172 may include nitride, and the second end spacer 174 may include oxide. The second insulating capping line 148B may include nitride. The second end spacer 174 may be formed to be thicker than the first end spacer 172. The second insulating capping line 148B may be formed to be thinner than the second end spacer 174. In some embodiments, the second insulating capping line 148B may be formed to conformally cover a top surface of the first insulating capping line 148A, a side surface of the second end spacer 174, and a portion of a top surface of the connection region isolation layer 115.

Subsequently, a logic filling layer 176 may be formed on the second insulating capping line 148B. The logic filling layer 176 may include oxide. In some embodiments, an uppermost end of the second insulating capping line 148B and an uppermost end of the logic filling layer 176 may be located at the same vertical level.

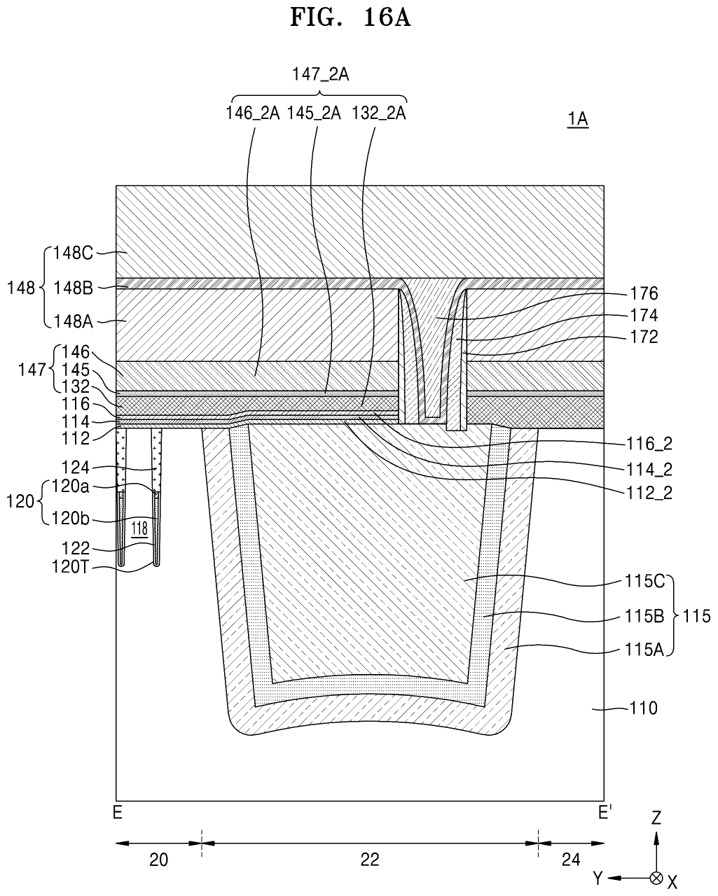

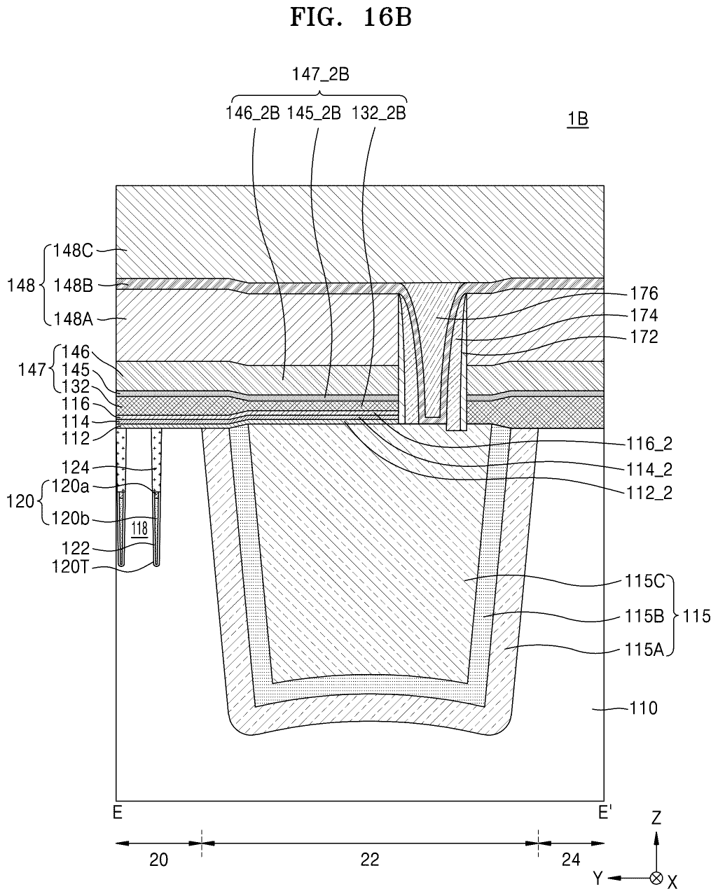

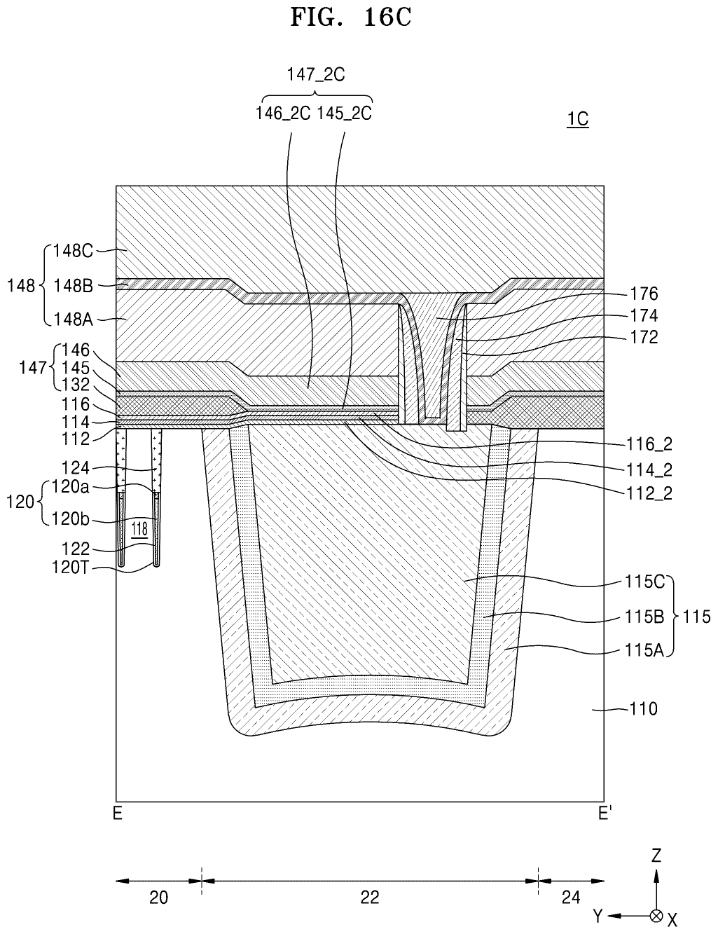

Referring to FIGS. 16A, 16B, and 16C, a third insulating capping line 148C may be formed on the logic filling layer 176 and the second insulating capping line 148B. For example, the third insulating capping line 148C may include nitride. The second insulating capping line 148B may be formed to have a less thickness than each of the first insulating capping line 148A and the third insulating capping line 148C.

Although embodiments have been described above with reference to the accompanying drawings, one of ordinary skill in the art will understand that inventive concepts may be implemented in other specific forms without changing the spirit or essential features thereof. Therefore, it should be understood that the embodiments described above should be understood as being illustrative and being not limited in all aspects.

While inventive concepts has been particularly shown and described with reference to an embodiment thereof, it will be understood that various changes in form and details may be made therein without departing from the spirit and scope of the following claims.

What is claimed is:

1. A semiconductor device comprising:
a substrate including a cell region and a connection region around the cell region;
a plurality of cell device isolation layers in the cell region of the substrate, the plurality of cell device isolation layers defining a plurality of active regions in the cell region of the substrate;
a cell word line extending across the plurality of active regions in a first horizontal direction on the cell region of the substrate;
a cell bit line including a cell metallic conductive pattern, the cell metallic conductive pattern extending on the cell region of the substrate in a second horizontal direction, the second horizontal direction intersecting the first horizontal direction; and
a connection bit line including a connection metallic conductive pattern, the connection metallic conductive pattern extending in the second horizontal direction on the connection region of the substrate, wherein
a top surface of the connection bit line is located at a vertical level that is equal to or lower than a top surface of the cell bit line, and
a height of the connection metallic conductive pattern in a vertical direction is equal to or greater than a height of the cell metallic conductive pattern in the vertical direction.

2. The semiconductor device of claim 1, further comprising:
a connection region isolation layer in the connection region of the substrate, wherein
a top surface of the connection region isolation layer is located at a higher vertical level than the substrate in the cell region.

3. The semiconductor device of claim 1, wherein
the cell bit line further includes a cell conductive semiconductor pattern between the cell metallic conductive pattern and the substrate,
the connection bit line further includes a connection conductive semiconductor pattern between the connection metallic conductive pattern and the substrate, and
a top surface of the connection conductive semiconductor pattern is located at a vertical level that is equal to or lower than a top surface of the cell conductive semiconductor pattern.

4. The semiconductor device of claim 1, wherein
a bottom surface of the connection bit line is located at a vertical level that is equal to or higher than a bottom surface of the cell bit line.

5. The semiconductor device of claim 1, wherein a thickness of the connection bit line in the vertical direction is less than a thickness of the cell bit line in the vertical direction.

6. The semiconductor device of claim 1, further comprising:
a connection insulating layer between the substrate in the connection region and the connection bit line, wherein
at least a portion of a bottom surface of the connection metallic conductive pattern is in direct contact with a top surface of the connection insulating layer.

7. The semiconductor device of claim 1, further comprising:
a connection region isolation layer in the connection region of the substrate, wherein
the plurality of active regions include an outer active region and at least one inner active region,
the outer active region is adjacent to the connection region isolation layer,
the at least one inner active region is spaced apart from the connection region isolation layer with the outer active region therebetween, and
a top surface of at least a portion of the cell bit line on the outer active region has a vertical level that is equal to or lower than a top surface of a remaining portion of the cell bit line disposed on the inner active region.

8. The semiconductor device of claim 1, further comprising:
a cell insulating layer between the substrate in the cell region and the cell bit line; and
a connection insulating layer between the substrate in the connection region and the connection bit line, wherein
a top surface of the connection insulating layer is located at a higher vertical level than a top surface of the cell insulating layer.

9. The semiconductor device of claim 1, wherein
a bottom surface of the connection metallic conductive pattern is at a vertical level that is equal to or lower than a bottom surface of the cell metallic conductive pattern.

10. A semiconductor device comprising:
a substrate including a cell region and a connection region around the cell region;
a plurality of cell device isolation layers in the cell region of the substrate, the plurality of cell device isolation layers defining a plurality of active regions in the cell region of the substrate;
a cell word line extending across the plurality of active regions in a first horizontal direction on the cell region of the substrate;
a cell bit line including a cell conductive semiconductor pattern, the cell conductive semiconductor pattern extending on the cell region of the substrate in a second horizontal direction, the second horizontal direction intersecting the first horizontal direction; and
a connection bit line including a connection conductive semiconductor pattern, the connection conductive semiconductor pattern extending in the second horizontal direction on the connection region of the substrate, wherein
the connection conductive semiconductor pattern includes a portion having a lower height in a vertical direction than a height of the cell conductive semiconductor pattern in the vertical direction.

11. The semiconductor device of claim 10, wherein a top surface of the connection conductive semiconductor pattern is located at a vertical level that is equal to or lower than a top surface of the cell conductive semiconductor pattern.

12. The semiconductor device of claim 10, wherein a bottom surface of the connection conductive semiconductor pattern is located at a vertical level that is equal to or higher than a bottom surface of the cell conductive semiconductor pattern.

13. The semiconductor device of claim 10, wherein
the cell bit line includes a cell metallic conductive pattern,
the connection bit line includes a connection metallic conductive pattern, and
a bottom surface of the connection metallic conductive pattern is located at a vertical level that is equal to or lower than a bottom surface of the cell metallic conductive pattern.

14. The semiconductor device of claim 10, wherein
the cell bit line includes a cell metallic conductive pattern,
the connection bit line includes a connection metallic conductive pattern, and
a height of the connection metallic conductive pattern in the vertical direction is equal to or greater than a height of the cell metallic conductive pattern in the vertical direction.

15. The semiconductor device of claim 10, wherein a height of the connection bit line in the vertical direction is less than a height of the cell bit line in the vertical direction.

16. The semiconductor device of claim 10, further comprising:
a connection region isolation layer in the connection region of the substrate, wherein
a top surface of the connection region isolation layer is located at a higher vertical level than the substrate in the cell region.

17. The semiconductor device of claim 10, wherein
the substrate further includes a peripheral circuit region spaced apart from the cell region with the connection region therebetween, and
a top surface of a portion of the connection conductive semiconductor pattern adjacent to the peripheral circuit region is located at a higher vertical level than a top surface of the cell conductive semiconductor pattern.

18. A semiconductor device comprising:
a substrate including a cell region and a connection region around the cell region;
a cell device isolation layer in the cell region of the substrate, the cell device isolation layer defining an active region in the cell region of the substrate; a cell word line extending across the active region in a first horizontal direction on the cell region of the substrate;
a cell bit line extending on the cell region of the substrate in a second horizontal direction, the second horizontal direction intersecting the first horizontal direction; and
a connection bit line extending in the second horizontal direction on the connection region of the substrate, wherein
the cell bit line includes a cell conductive semiconductor pattern and a cell metallic conductive pattern on the cell conductive semiconductor pattern,
the connection bit line includes a connection conductive semiconductor pattern and a connection metallic conductive pattern on the connection conductive semiconductor pattern,
the cell conductive semiconductor pattern and the connection conductive semiconductor pattern each include polysilicon,
a top surface of the connection conductive semiconductor pattern is located at a vertical level that is equal to or lower than a top surface of the cell conductive semiconductor pattern, and
a vertical level difference between a top surface of the connection metallic conductive pattern and a top surface of the cell metallic conductive pattern is equal to or less than a vertical level difference between a bottom surface of the connection metallic conductive pattern and a bottom surface of the cell metallic conductive pattern.

19. The semiconductor device of claim 18, wherein a bottom surface of the connection conductive semiconductor pattern is located at a vertical level that is equal to or higher than a bottom surface of the cell conductive semiconductor pattern.

20. The semiconductor device of claim 18, wherein a height of the connection bit line in a vertical direction is less than a height of the cell bit line in the vertical direction.
